(19) United States
(12) Patent Application Publication
(10) Pub. No.: US 2024/0392442 A1
(43) Pub. Date: Nov. 28, 2024

(54) PLASMA DEVICE FOR POWDER SURFACE TREATMENT USING HORIZONTAL ELECTRODE

(71) Applicant: INOPLAZTECH CO., LTD., Ulsan (KR)

(72) Inventors: Deuk Yeon LEE, Ulsan (KR); Chang Young LEE, Ulsan (KR); Ja Eun LEE, Ulsan (KR); Yeon Bi HAN, Ulsan (KR)

(73) Assignee: INOPLAZTECH CO., LTD., Ulsan (KR)

(21) Appl. No.: 18/695,900

(22) PCT Filed: May 22, 2023
(86) PCT No.: PCT/KR2023/006908

§ 371 Date: Mar. 27, 2024

(30) Foreign Application Priority Data
May 24, 2022 (KR) 10-2022-0063293
May 18, 2023 (KR) 10-2023-0064329
May 18, 2023 (KR) 10-2023-0064330
May 18, 2023 (KR) 10-2023-0064331
May 18, 2023 (KR) 10-2023-0064332
May 18, 2023 (KR) 10-2023-0064333
May 18, 2023 (KR) 10-2023-0064334

(51) Int. Cl. C23C 16/509; C23C 16/44

(52) U.S. Cl. CPC C23C 16/5096; C23C 16/4417

(57) ABSTRACT

A plasma device for powder surface treatment using a horizontal electrode, according to the present invention, is advantageous in that, by placing powders on a flat plate-shaped horizontal electrode arranged in the horizontal direction and treating same with plasma, there is almost no loss of powder, and more rapid and uniform surface treatment is possible.

### TECHNICAL FIELD

The present invention relates to a plasma device for powder surface treatment using a horizontal electrode, and more particularly, to a plasma device for powder surface treatment using a horizontal electrode, in which, by applying vibration to the horizontal electrode, nano- or micro-sized powder can be more uniformly surface-treated on the horizontal electrode.

### BACKGROUND ART

In general, since carbon nano-powder materials such as carbon nanotubes, graphene etc. are easily mutually aggregated to each other in spite of having excellent physical properties, dispersion technology that allows the carbon nano-powder materials to be uniformly mixed with a base material or solvent, is essential for commercialization.

Dispersion technology according to the related art can be classified into mechanical methods such as ultrasonic waves and milling, wet methods using a chemical reaction of strong acids and surfactants, and dry methods using plasma.

Mechanical or wet methods involve problems such as complex processes, long processing time, damage to materials, impurity residue, wastewater generation, etc.

On the other hand, a dry plasma method is preferred considering mass production and environmental friendliness, but, in order to perform plasma surface treatment on nano-powder, a device for rotating and stirring powder is necessary to uniformly treat nano-powder, and as the size of the powder is decreased, it is very difficult to perform uniform surface treatment, and functionalization efficiency is low, and processing time is long.

Recently, a technology of mixing powder using mechanical methods such as rotation or stirring have been adopted in eco-friendly plasma dry methods, but functionalization efficiency is low, and even if rotation or stirring is performed, it is very difficult to treat a large amount of powder floating within a chamber uniformly.

### DETAILED DESCRIPTION OF THE INVENTION

### Technical Problem

The present invention provides a plasma device for powder surface treatment using a horizontal electrode, in which costs can be reduced and mass production can be improved.

### Technical Solution

According to an aspect of the present invention, there is provided a plasma device for powder surface treatment using a horizontal electrode, the plasma device including: a chamber that defines a space in which plasma is generated; a horizontal electrode installed inside the chamber in a horizontal direction, having a flat plate shape so that powders is put on the upper surface of the horizontal electrode and configured to generate plasma when power is applied to the horizontal electrode, to functionalize the powder by performing surface treatment on the powder; and a vibration generator configured to apply vibration to the horizontal electrode to allow a position of the powders to be changed on the upper surface of the horizontal electrode, thereby uniformly surface-treating the powders.

The horizontal electrode may include a porous filter electrode having a plurality of holes formed therein.

The plasma device may further include an adsorption unit configured to adsorb the powders onto the upper surface of the filter electrode by reducing internal pressure of the filter electrode.

The vibration generator may apply vibration to the horizontal electrode so that the horizontal electrode can perform at least one of up and down motion, left and right motion rotation and gyro motion.

The vibration generator may include a vibration motor connected to the horizontal electrode and configured to apply vibration to the horizontal electrode by a rotational force when power is applied to the horizontal electrode.

The vibration generator may include an air knocker provided under the horizontal electrode and configured to apply vibration to the horizontal electrode by moving a piston by compressed air.

The vibration generator may include an electronic hammer provided under the horizontal electrode and configured to apply vibration to the horizontal electrode using an electromagnetic force generated when power is applied to the electronic hammer.

The vibration generator may include an ultrasonic vibrator provided under the horizontal electrode and configured to apply vibration to the horizontal electrode using ultrasonic waves generated when power is applied to the ultrasonic vibrator.

The vibration generator may include an acoustic vibration module connected to a lower part of the horizontal electrode by a connection member and configured to generate and resonate sound to apply acoustic vibration to the horizontal electrode.

A plurality of the horizontal electrode may be stacked in a vertical direction and may be arranged to be spaced apart from each other by a certain distance.

The plasma device may further include a powder supply unit configured to supply the powder to the upper surface of the horizontal electrode, and a controller configured to control a vibration intensity of the vibration generator according to an amount of the powder supplied from the powder supply unit.

According to another aspect of the present invention, there is provided a plasma device for powder surface treatment using a horizontal electrode, the plasma device including: a chamber that defines a space in which plasma is generated; horizontal electrodes installed inside the chamber in a horizontal direction, a plurality of horizontal electrodes being stacked in a vertical direction and arranged to be spaced apart from each other by a certain distance, having a flat plate shape so that powder is put on each upper surface of the horizontal electrode and configured to generate plasma when power is applied to the horizontal electrode, to functionalize the powder by performing surface treatment on the powder; a vibration generator configured to apply mechanical vibration to the horizontal electrode to allow a position of the powders to be changed on the upper surface of the horizontal electrode, thereby uniformly surface-treating the powders; a powder supply unit configured to supply the powder to the upper surface of the horizontal electrode; and a controller configured to control a vibration intensity of the vibration generator according to the amount of the powder supplied from the powder supply unit.

### Effects of the Invention

A plasma device for a powder surface treatment using a horizontal electrode according to the present invention is advantageous in that, by placing powders on a flat plate-shaped horizontal electrode arranged in a horizontal direction and treating same with plasma, a phenomenon that powders are deviated from the surface of the horizontal electrode and float in the air, occurs hardly and powders are treated while being in contact with the surface of the horizontal electrode so that the loss of powders occurs hardly and surface treatment can be more quickly and uniformly performed.

Furthermore, it is also advantageous in that, by applying vibration to the horizontal electrode during plasma treatment to give the effect of tapping the horizontal electrode, the position of powder located relatively closer to the surface of the horizontal electrode and the position of powder located further away therefrom are repeatedly changed, thereby enabling more uniform surface treatment of powders.

In addition, by vertically stacking a plurality of horizontal electrodes, the volume that can be treated at one time is adjustable.

Furthermore, by heating the horizontal electrodes while plasma treatment is performed using a heater, the residual moisture of powders is removed so that reactivity can be increased.

Moreover, vibration is applied to the horizontal electrodes by heating the horizontal electrodes, so that a re-aggregation phenomenon is prevented when the residual moisture of powders is removed, and powders can be maintained in a uniformly dispersed state even after being dried.

In addition, by arranging a magnet on the horizontal electrode, the additional movement of electron is generated to increase plasma density so that surface treatment speed can be enhanced.

Furthermore, a texture pattern is formed on the surface of the horizontal electrode so that, when powders are moved by vibration of the horizontal electrode, powder may collide with a pattern layer, and collision energy can be additionally utilized and thus, the effect of plasma treatment can be enhanced.

Moreover, by applying power to the horizontal electrodes that is a first electrode unit and grounding a rack that is a second electrode unit, plasma is formed between the first electrode unit and the second electrode unit so that the efficiency and uniformity of surface treatment of powders can be enhanced.

In addition, by grounding the second electrode unit, the energy effect of ions that collide with the first electrode unit is increased so that the effect of surface treatment of powders can be further enhanced.

Furthermore, the second electrode unit includes a cover electrode coupled to the rack and arranged to face the upper surface of the horizontal electrode so that plasma can be concentrated in a space between the horizontal electrode and the cover electrode and thus the effect of surface treatment of powders on the upper surface of the horizontal electrode can be further enhanced.

In addition, by including the first electrode unit and the second electrode unit, alternating current (AC) power in addition to radio frequency (RF) power can be used.

Moreover, by supplying a plasma reaction gas and a gaseous coating source, the coating source can be more uniformly and strongly coated on the surface of the powders by plasma polymerization.

In addition, by mixing a grinding medium as well as powder with the horizontal electrode and supplying a mixture thereof, when powder is plasma surface-treated while applying vibration to the horizontal electrode, the powders can be more finely ground while colliding with the grinding mediums so that the sizes of the powders are decreased and surface treatment efficiency can be further enhanced.

### DESCRIPTION OF THE DRAWINGS

FIG. 1 is a configuration diagram schematically illustrating a plasma device for powder surface treatment using a horizontal electrode according to a first embodiment of the present invention.

FIG. 2 is a side view illustrating the horizontal electrode shown in FIG. 1.

FIG. 3 is a cross-sectional view illustrating a horizontal electrode according to a second embodiment of the present invention.

FIG. 4 is a diagram schematically illustrating a plasma device for powder surface treatment using a horizontal electrode according to a third embodiment of the present invention.

FIG. 5 is a diagram schematically illustrating a plasma device for powder surface treatment using a horizontal electrode according to a fourth embodiment of the present invention.

FIG. 6 is a diagram schematically illustrating a plasma device for powder surface treatment using a horizontal electrode according to a fifth embodiment of the present invention.

FIG. 7 is a side view illustrating a flat electrode shown in FIG. 6.

FIG. 8 is a graph for comparing the functionalization of a flat electrode and a filter electrode according to an embodiment of the present invention.

FIG. 9 is a diagram schematically illustrating a plasma device for powder surface treatment using a horizontal electrode according to a sixth embodiment of the present invention.

FIG. 10 is a diagram schematically illustrating the horizontal electrode shown in FIG. 9.

FIG. 11 is a diagram illustrating an example in which a plasma device for powder surface treatment using a horizontal electrode according to the sixth embodiment of the present invention is performed in a semi-continuous process.

FIG. 12 is a diagram schematically illustrating another example of a horizontal electrode according to the sixth embodiment of the present invention.

FIG. 13 is a diagram schematically illustrating another example of a heater in the plasma device for powder surface treatment using a horizontal electrode according to the sixth embodiment of the present invention.

FIG. 14 is a diagram schematically illustrating a plasma device for powder surface treatment using a horizontal electrode according to a seventh embodiment of the present invention.

FIG. 15 is a diagram schematically illustrating the horizontal electrode shown in FIG. 14.

FIG. 16 is a diagram illustrating an example in which a plasma device for powder surface treatment using a horizontal electrode according to the seventh embodiment of the present invention is performed in a semi-continuous process.

FIG. 17 is a diagram schematically illustrating another example of a horizontal electrode according to the seventh embodiment of the present invention.

FIG. 18 is a diagram schematically illustrating another example of a magnetic force generator in a plasma device for powder surface treatment using a horizontal electrode according to the seventh embodiment of the present invention.

FIG. 19 is a diagram schematically illustrating a plasma device for powder surface treatment using a horizontal electrode according to an eighth embodiment of the present invention.

FIG. 20 is a diagram schematically illustrating the horizontal electrode shown in FIG. 19.

FIG. 21 is a diagram illustrating an example in which the plasma device for powder surface treatment using a horizontal electrode according to the eighth embodiment of the present invention is performed in a semi-continuous process.

FIG. 22 is a diagram schematically illustrating another example of a horizontal electrode according to the eighth embodiment of the present invention.

FIG. 23 is a diagram schematically illustrating another example of a horizontal electrode according to the eighth embodiment of the present invention.

FIG. 24 is a diagram schematically illustrating a plasma device for powder surface treatment using a horizontal electrode according to a ninth embodiment of the present invention.

FIG. 25 is a diagram schematically illustrating the horizontal electrode shown in FIG. 24.

FIG. 26 is a diagram illustrating an example in which the plasma device for powder surface treatment using a horizontal electrode according to the ninth embodiment of the present invention is performed in a semi-continuous process.

FIG. 27 is a diagram schematically illustrating a plasma device for powder surface treatment using a horizontal electrode according to a tenth embodiment of the present invention.

FIG. 28 is a diagram schematically illustrating a plasma device for powder surface treatment using a horizontal electrode according to an eleventh embodiment of the present invention.

FIG. 29 is a diagram schematically illustrating the horizontal electrode shown in FIG. 28.

FIG. 30 is a diagram illustrating an example in which the plasma device for powder surface treatment using a horizontal electrode according to the eleventh embodiment of the present invention is performed in a semi-continuous process.

FIG. 31 is a diagram schematically illustrating another example of a horizontal electrode according to the eleventh embodiment of the present invention.

FIG. 32 is a diagram schematically illustrating another example of a coating source supply unit in a plasma device for powder surface treatment using a horizontal electrode according to the eleventh embodiment of the present invention.

FIG. 33 is a diagram schematically illustrating a plasma device for powder surface treatment using a horizontal electrode according to a twelfth embodiment of the present invention.

FIG. 34 is a diagram schematically illustrating the horizontal electrode shown in FIG. 33.

FIG. 35 is a diagram illustrating an example in which the plasma device for powder surface treatment using a horizontal electrode according to the twelfth embodiment of the present invention is performed in a semi-continuous process.

FIG. 36 is a diagram schematically illustrating another example of a horizontal electrode according to the twelfth embodiment of the present invention.

### MODE OF THE INVENTION

Hereinafter, embodiments of the present invention will be described in detail with reference to the accompanying drawings.

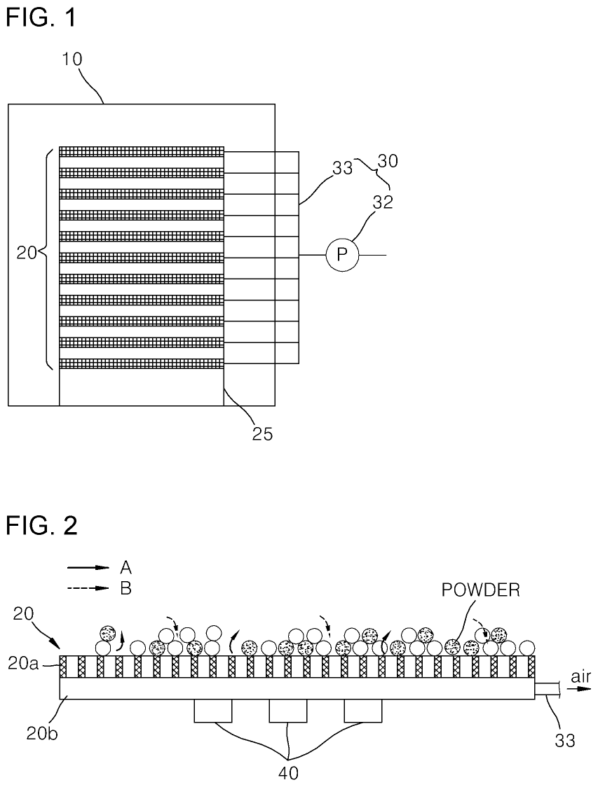

FIG. 1 is a configuration diagram schematically illustrating a plasma device for powder surface treatment using a horizontal electrode according to a first embodiment of the present invention. FIG. 2 is a side view illustrating ae filter electrode shown in FIG. 1.

Referring to FIGS. 1 and 2, in the plasma device for powder surface treatment using a horizontal electrode according to the first embodiment of the present invention, an example in which a horizontal electrode is a porous filter electrode 20 (hereinafter, referred to as a filter electrode) having a plurality of holes formed therein, will be described.

The powder includes nano-sized or micro-sized powder such as carbon nanotube, graphene, etc.

The plasma device for powder surface treatment using a horizontal electrode includes a chamber 10, a filter electrode 20, an adsorption unit 30, and a vibration generator.

The plurality of filter electrodes 20 are accommodated in the chamber 10, and the chamber 10 defines a space in which plasma is generated. A power supplying device (not shown) and a gas supplying unit (not shown) that supplies external gas are connected to the chamber 10. The chamber 10 is grounded and serves as a ground electrode.

A rack 25 into which the plurality of filter electrodes 20 are inserted, is provided in the chamber 10. However, the present invention is not limited thereto, and it also possible to stack the plurality of filter electrodes 20 to be spaced apart from each other by a certain distance in a vertical direction, without using the rack 25.

The rack 25 may also be fixedly installed into the chamber 10 or may be installed to be picked out from the chamber 10 so that the rack 25 may also be brought into the chamber 10 again after the plurality of filter electrodes 20 are inserted into the rack 25.

The filter electrode 20 may be a power supply electrode to which power is supplied from the power supplying device (not shown). The filter electrode 20 generates plasma inside the chamber 10 when power is applied from the power supplying device (not shown) and gas is supplied from the gas supply unit (not shown) into the chamber 10. In the present embodiment, an example in which the chamber 10 is a ground electrode, will be described, but the present invention is not limited thereto, and the filter electrode 20 may also include an electrode having a potential difference between one side and the other side of the filter electrode 20 to generate plasma.

Plasma generated in the filter electrode 20 is used to functionalize the powder by surface treatment. Through surface functionalization of the powder, the powders are dispersed not to be aggregated without degradation of existing physical properties, and an interfacial bonding force between the powder and other heterogeneous materials can be enhanced.

The filter electrode 20 is arranged in the chamber 10 in a horizontal direction and has a flat plate shape so that the powder may be put on the upper surface of the filter electrodes 20. An example in which the filter electrode 20 has a rectangular plate shape, will be described, but the present invention is not limited thereto, and the filter electrode 20 may also have a circular plate shape.

The plurality of filter electrodes 20 are arranged to have separation spaces therebetween in the vertical direction or the horizontal direction. In the present embodiment, an example in which 10 filter electrodes 20 are inserted into the rack 25 to be spaced apart from each other by a certain distance in the vertical direction, will be described. The number of stacks of the filter electrodes 20 may be adjusted according to the volume of treatment.

The filter electrode 20 is a porous filter electrode having a plurality of holes formed therein. The filter electrodes 20 includes a filter unit 20a formed of a porous material or porous mesh, and a vacuum unit 20b that is formed under the filter unit 20a and brought into a vacuum state by a vacuum pump 32 to be described later. The filter electrode 20 may also be formed so that only the upper surface of the filter electrode 20 has a porous structure. The plurality of holes may be processed in nano or micro unit size and may have a smaller size than the size of the powder or may be provided with nano nonwoven fabrics so that the powder cannot pass therethrough. In the present embodiment, an example in which the holes have a size of about 100 to 1000 nm, will be described. Moreover, an example in which the filter electrode 20 is formed of stain use stainless (SUS) so that the holes can be formed in the filter electrode 20, will be described.

The adsorption unit 30 is a unit that adsorbs the powder onto the surface of the filter electrode 20 by reducing an internal pressure of the filter electrode 20.

The adsorption unit 30 includes a vacuum pump 32, a vacuum flow path 33, and a powder blocking unit (not shown) for filtering the powder.

The vacuum pump 32 is installed outside the chamber 10 and inhales the air from an inside of the plurality of filter electrodes 20, thereby forming the inside of the plurality of filter electrodes 20 in a vacuum state.

The vacuum flow path 33 is a flow path that connects the vacuum pump 32 and each lower part of the plurality of filter electrodes 20 to each other. One end of the vacuum flow path 33 is connected to each lower part of the plurality of filter electrodes 20, and the other end of the vacuum flow path 33 is connected to the vacuum pump 32. The vacuum flow path 33 is connected to the vacuum unit 20b of the filter electrodes 20.

However, the present invention is not limited thereto, and the vacuum pump 32 may also be installed in each lower part of the filter electrode 20 and may also be installed in the rack 25.

The vibration generator is a device for applying vibration to the filter electrode 20 so that the position of the powders may be changed on the upper surface of the filter electrodes 20 and thus the powders may be uniformly surface-treated. The vibration generator may generate vibration such as the effect of tapping the lower part of the filter electrode 20, thereby changing the position of powder located relatively closer to the surface of the filter electrode 20 and the position of powder located further away from the surface of the filter electrode 20. Thus, the powders put on the upper surface of the filter electrode 20 may be uniformly surface-treated.

The vibration generator may generate at least one of mechanical vibration, acoustic vibration, and ultrasonic vibration, thereby applying vibration to the filter electrode 20. In addition, the vibration generator (not shown) may apply vibration so that the filter electrode 20 may perform various behaviors such as up and down motion, left and right motion, rotation, and gyro motion, and the like. Furthermore, the vibration generator (not shown) may apply vibration discontinuously or periodically.

In the present embodiment, an example in which the vibration generator is an ultrasonic vibrator 40, will be described.

Referring to FIG. 2, the ultrasonic vibrator 40 is provided under the filter electrode 20, generates ultrasonic waves according to power supplied from the power supplying device (not shown), and applies vibration to the filter electrode 20 using the same.

Meanwhile, the plasma device for powder surface treatment using a horizontal electrode includes a powder supply unit (not shown) that supplies the powders onto the upper surface of the filter electrode 20.

The powder supply unit (not shown) will be described as an example in which the powder supply unit (not shown) is provided separately from the chamber 10, supplies the powders to the upper surface of the filter electrode 20 before arranging the filter electrode 20 in the chamber 10 and then the filter electrode 20 are arranged in the chamber 10 on which the powders are put, will be described. However, the present invention is not limited thereto, and the powder supply unit (not shown) is provided inside the chamber 10 so that the filter electrode 20 may also supply the powders to the upper surface of the filter electrode 20 arranged in the chamber 10. The powder supply unit (not shown) may be arranged in each separation space between the plurality of filter electrodes 20 and may also spray the powders into the separation spaces at one time, and one powder sprayer (not shown) may be installed to be movable in the vertical direction and may continuously spray the powders into each separation space between the filter electrodes 20. In addition, the powder sprayer (not shown) may also spray the powder into the chamber 10.

Since the filter electrode 20 has a flat plate shape, it is easy to put the powders on the upper surface of the filter electrode 20 through the powder supply unit (not shown).

An operation of a plasma device according to the first embodiment of the present invention having the above configuration will be described as below.

After the powder is put on each upper surface of the plurality of filter electrodes 20, the filter electrodes 20 are inserted into the rack 24 and stacked.

In the present embodiment, an example in which the plurality of filter electrodes 20 are inserted into the rack 25 and are stacked, will be described, but the present invention is not limited thereto, and the plurality of filter electrodes 20 may also be stacked to be spaced apart from each other by a certain distance without using the rack 25.

Furthermore, the present invention is not limited to the above embodiment, and the powder may also be supplied to the plurality of filter electrodes 20 that are mounted inside the chamber 10 in advance.

When the vacuum pump 32 is activated, the internal pressure of the vacuum unit 20b of the filter electrodes 20 is reduced by an inhalation pressure of the vacuum pump 32.

When the inside of the vacuum unit 20b of the filter electrodes 20 is in a vacuum state, the powder is adsorbed onto the surface of the filter electrodes 20. That is, an adsorption force B acts on the powders in a direction toward the surface of the filter electrodes 20.

In addition, when the ultrasonic vibrator 40 is activated, vibration is applied to the filter electrodes 20 by the ultrasonic vibrator 40.

When vibration is applied to a lower part of the filter electrode 20, the position of the powders is changed, and the powders are uniformly dispersed on the upper surface of the filter electrodes 20. Since the ultrasonic vibrator 40 generates the effect of tapping the filter electrode 20, the position of the powder located relatively closer to the surface of the filter electrode 20 and the position of the powder located relatively further from the surface of the filter electrode 20 are changed.

That is, referring to FIG. 2, the adsorption force B in the direction toward the surface of the filter electrodes 20 and a dispersion force in a direction of bouncing from the surface of the filter electrode 20 act on the powders put on the filter electrode 20. At this time, the adsorption force B and the dispersion force A may be adjusted according to the inhalation force of the vacuum pump 30 and a vibration intensity of the ultrasonic vibrator 40. The adsorption force B and the dispersion force A may be calculated as optimum values through experiments or the like. The adsorption force B and the dispersion force A may be properly adjusted so that only the position movement of the powders is possible without flying from the surface of the filter electrode 20 and the powders can be uniformly plasma surface-treated.

Furthermore, when the plurality of filter electrodes 20 are stacked in the vertical direction, the filter electrodes 20 are spaced apart from each other by a preset distance and the vibration intensity of the vibration generator (not shown) is set higher a certain level, when vibration is applied to the filter electrodes 20, the powder bouncing from the filter electrodes 20 on the lower side among the filter electrodes 20 may be surface-treated while being in contact with the surface of the filter electrodes 20 on the upper side.

In addition, the powder can be prevented from being stacked above a certain thickness in a specific portion of the surface of the filter electrode 20.

Moreover, the effect of tapping the filter electrode 20 using the ultrasonic vibrator 40 is given so that there is no need to completely remove the powder from the surface of the filter electrode 20, to float and disperse the powder and then to adsorb the powder and thus, a treatment time can be reduced compared to the case where the powder is floated.

Thus, position movement is possible in a state in which the powders are adsorbed onto the surface of the filter electrode 20, and the powders are uniformly mixed so that the powders may be uniformly surface-treated by plasma.

A process in which the powder is surface-treated by the plasma, can be performed for a preset time. When the set time has elapsed, plasma treatment is stopped, and the powder is collected.

As described above, in the plasma device for powder surface treatment using a horizontal electrode according to the first embodiment of the present invention, since the powders is placed on a plurality of horizontal electrodes, the structure is simple and the number of stacks of the horizontal electrodes may be increased so that the volume that can be treated at one time can be maximized.

In addition, since the powders are put on the surface of the horizontal electrodes, compared to the case of adsorption after the powders are floated, the amount of powders discarded without being treated can be minimized, a repeated process of repeating completely removing the powders from the surface of the filter electrode 20 and then dispersing the powders is not required so that processing efficiency can be improved.

Furthermore, vibration may be applied to the filter electrode 20 using the vibration generator so that the adsorption force B and the dispersion force A can be properly adjusted and the position movement of the powders is possible while the powders do not fly from the surface of the filter electrode 20 and the powders can be uniformly plasma surface-treated.

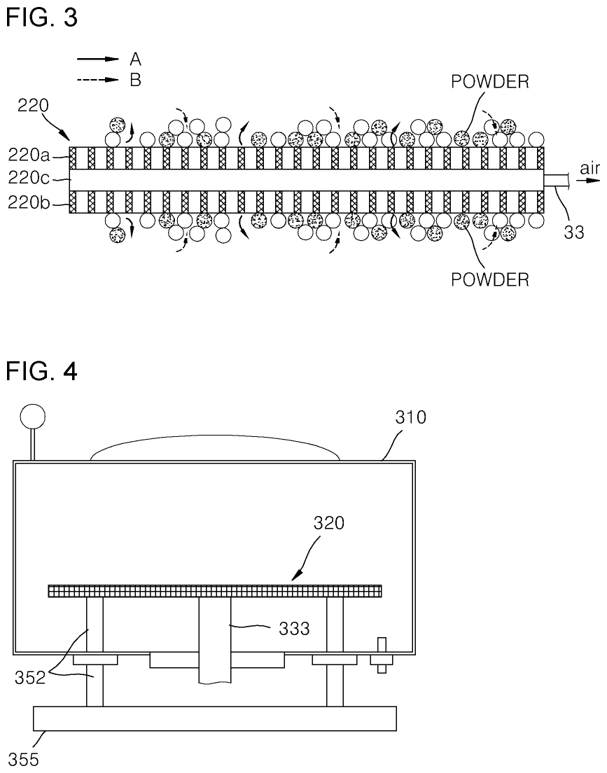

Meanwhile, FIG. 3 is a cross-sectional view of a horizontal electrode according to a second embodiment of the present invention.

Referring to FIG. 3, in the second embodiment of the present invention, an example in which a horizontal electrode is a porous filter electrode 220, will be described, and the second embodiment is different from the first embodiment in that the filter electrode 220 includes a top filter unit 220a, a bottom filter unit 220b and a vacuum unit 220c, and the other configurations and operations of the second embodiment are similar to those of the first embodiment and thus, different configurations will be mainly described, and detailed descriptions of similar configurations will be omitted.

The filter electrode 220 is formed to have a porous structure, and the plurality of filter electrodes 220 are stacked to have separation spaces in the vertical direction.

The top filter unit 220a and the bottom filter unit 220b are formed of a porous material or porous mesh. It is preferable that the top filter unit 220a and the bottom filter unit 220b are processed in nano or micro unit size and have a smaller size than the size of the powder or the top filter unit 220a and the bottom filter unit 220b are provided with nano nonwoven fabrics so that the powder cannot pass therethrough.

The vacuum unit 220c is formed between the top filter unit 220a and the bottom filter unit 220b and thus is in a vacuum state by the vacuum pump 32. A vacuum flow path 33 is connected to the vacuum unit 220c.

When the vacuum pump 32 is activated, the vacuum pump 32 inhales the air inside the vacuum unit 220c so that the inside of the vacuum unit 220c may be in a vacuum state.

When the inside of the vacuum unit 220c is in a vacuum state, the powder supplied to the inside of the chamber 10 or the periphery of the filter electrodes 220 may be adsorbed onto the surface of the top filter unit 220a and the bottom filter unit 220b.

Thus, powders may be adsorbed onto the upper and lower surfaces of the filter electrode 220 and plasma surface-treated so that the volume of plasma treatment can be increased.

Meanwhile, FIG. 4 is a diagram schematically illustrating a plasma device for powder surface treatment using a horizontal electrode according to a third embodiment of the present invention.

Referring to FIG. 4, in the plasma device for powder surface treatment using a horizontal electrode according to the third embodiment of the present invention, an example in which a horizontal electrode is a porous filter electrode 320, will be described, and the third embodiment is different from the first embodiment in that the plasma device for powder surface treatment using a horizontal electrode according to the third embodiment includes a chamber 310, a filter electrode 320, an adsorption unit 330 and a vibration generator and the vibration generator is an acoustic vibration module 355, and the other configurations and operations of the third embodiment are similar to those of the first embodiment and thus, different configurations will be mainly described, and detailed descriptions of similar configurations will be omitted.

The acoustic vibration module 355 is an acoustic resonance vibrator that generates and resonates sound to generate acoustic vibration in the filter electrode 320.

The upper portion of the acoustic vibration module 355 is connected to the filter electrode 320 by a connection member 352.

In the present embodiment, an example in which one filter electrode 320 is disposed, will be described, but the present invention is not limited thereto, and a plurality of filter electrodes 320 may be arranged to be spaced apart from each other by a certain distance in the vertical direction or the horizontal direction.

A vacuum flow path 333 connected to a vacuum pump (not shown) is connected to the inside of the filter electrode 320.

In addition, a rack is provided inside the chamber so that the filter electrode 320 can be inserted into the rack, and a shock absorbing member (not shown) that absorbs shock when the filter electrode 320 vibrates, may be provided between the rack and the filter electrode 320.

In the plasma device for powder surface treatment using a horizontal electrode according to the third embodiment of the present invention, an example in which the horizontal electrode is the porous filter electrode 320, has been described, but the present invention is not limited thereto, and a flat electrode that is not a porous electrode may also be used. When the flat electrode is used, the adsorption unit may be omitted.

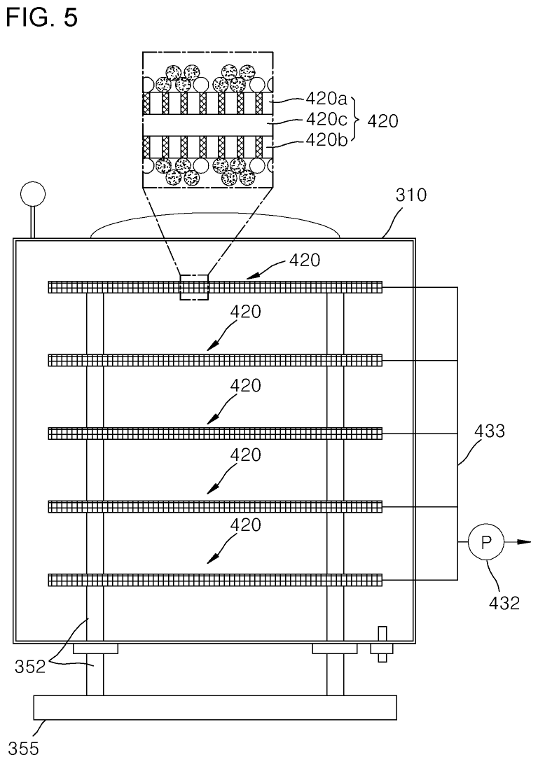

Meanwhile, FIG. 5 is a diagram schematically illustrating a plasma device for powder surface treatment using a horizontal electrode according to the fourth embodiment of the present invention.

Referring to FIG. 5, in the plasma device for powder surface treatment using a horizontal electrode according to the fourth embodiment of the present invention, an example in which a horizontal electrode is a porous filter electrode 420, will be described, and the fourth embodiment is different from the third embodiment in that the plurality of horizontal electrodes 420 are arranged to be spaced apart from each other by a certain distance in the vertical direction and each of the filter electrodes 420 includes a top filter unit 420a, a bottom filter unit 420b and a vacuum unit 420c, and the other configurations and operations of the forth embodiment are similar to those of the third embodiment and thus, different configurations will be mainly described, and detailed descriptions of similar configurations will be omitted.

The plurality of filter electrodes 420 are stacked in the vertical direction to have separation spaces therebetween. The number of stacks of the filter electrodes 420 may be adjusted according to the volume of treatment.

The top filter unit 420a and the bottom filter unit 420b are formed of a porous material or porous mesh. It is preferable that the top filter unit 420a and the bottom filter unit 420b are processed in nano or micro unit sizes and holes of the top filter unit 420a and the bottom filter unit 420b are formed smaller than the size of the powder so that the powder cannot pass through the holes.

The vacuum unit 420c is formed between the top filter unit 420a and the bottom filter unit 420b and thus is in a vacuum state by the vacuum pump 432. A vacuum flow path 433 is connected to the vacuum unit 420c.

When the vacuum pump 432 is activated, the vacuum pump 432 inhales the air inside the vacuum unit 420c so that the inside of the vacuum unit 420c may be in a vacuum state.

When the inside of the vacuum unit 420c is in a vacuum state, the powder supplied to the inside of the chamber 10 or the periphery of the filter electrodes 220 may be adsorbed onto the surface of the top filter unit 420a and the bottom filter unit 420b.

Thus, powder may be adsorbed onto the upper and lower surfaces of the filter electrode 420 and plasma surface-treated so that the volume of plasma treatment can be increased.

In the above embodiment, an example in which the vacuum unit 420c of the plurality of filter electrodes 420 is in a vacuum state by one vacuum pump 432, has been described, but the present invention is not limited thereto, and a vacuum flow path and a vacuum pump may also be connected to a vacuum unit 420c of each of the plurality of filter electrodes 420.

Furthermore, a powder sprayer (not shown) that supplies the powder by spraying the powder is provided in separation spaces between the plurality of filter electrodes 420.

The powder sprayer (not shown) may be arranged in each separation space between the plurality of filter electrodes 420 and may spray the powders into the separation spaces at one time, and one powder sprayer (not shown) may be installed to be movable in the vertical direction and may also continuously spray the powders into each separation space between the filter electrodes 420. In addition, the powder sprayer (not shown) may also spray the powders to the inside of the chamber 310.

In the plasma device for powder surface treatment using a horizontal electrode according to the fourth embodiment of the present invention, any vibration generator that may generate at least one of mechanical vibration, acoustic vibration, and ultrasonic vibration, to apply vibration to the filter electrode 420 may also be used.

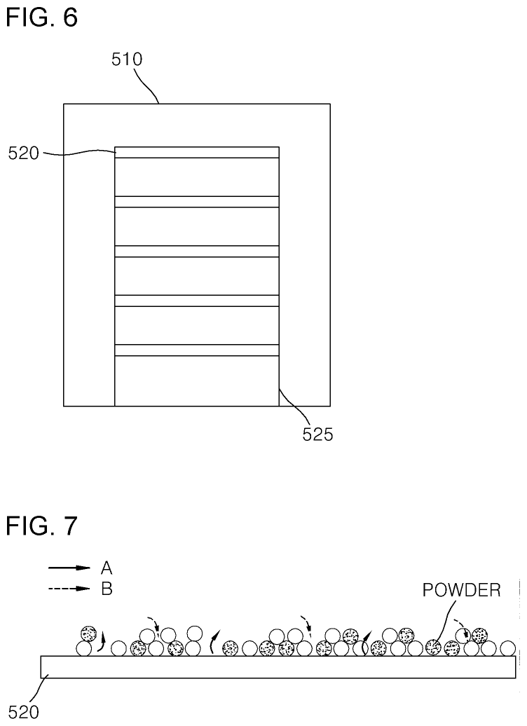

Meanwhile, FIG. 6 is a diagram schematically illustrating a plasma device for powder surface treatment using a horizontal electrode according to a fifth embodiment of the present invention. FIG. 7 is a side view illustrating the horizontal electrode shown in FIG. 6.

In the plasma device for powder surface treatment using a horizontal electrode according to the fifth embodiment of the present invention, the fifth embodiment is different from the first embodiment in that a horizontal electrode is a panel-shaped flat electrode 520 in which holes are not formed and the vibration generator 540 is a mechanical vibrator, and the other configurations and operations of the fifth embodiment are similar to those of the first embodiment and thus, different configurations will be mainly described, and detailed descriptions of similar configurations will be omitted.

At least one or more flat electrodes 520 are installed inside the chamber 510 in the horizontal direction, and the flat electrodes 520 have a flat plate shape so that the powders may be put on the upper surface of the flat electrodes 520. In the present embodiment, an example in which the flat electrode 520 has a flat plate shape, has been described, but the present invention is not limited thereto, and any flat electrode 520 having an upper surface on which the powder may be put, such as bowls, etc., may also be used.

The flat electrode 520 does not have a porous structure and thus may be manufactured of various materials such as metal, polymer, ceramics, etc. The flat electrode 520 may also be manufactured of aluminum among metals so that the flat electrode 520 is lighter than other metals such as stainless, etc. and costs can be reduced.

The vibration generator (not shown) is a device that is provided on the flat electrode 520 and allows the position of the powder to be changed on the upper surface of the flat electrode 520 so that the powders can be uniformly surface-treated.

An example in which the vibration generator (not shown) generates mechanical vibration when power is applied to the vibration generator (not shown) by the power supplying device, will be described. However, the present invention is not limited thereto, and the vibration generator (not shown) may also be an ultrasonic vibrator or an acoustic vibration module.

The vibration generator (not shown) includes at least one of a vibration motor (not shown) that applies vibration to the flat electrode 520 by a rotational force when power is applied to the vibration generator (not shown), an air knocker (not shown) that applies vibration to the flat electrode 520 by moving a piston by a compressed air, and an electronic hammer (not shown) that applies vibration to the flat electrode 520 using an electromagnetic force generated when power is applied to the electronic hammer (not shown). However, the present invention is not limited thereto, and the vibration generator (not shown) may apply vibration to the flat electrode 520 so that the flat electrode 520 may perform various behaviors such as up and down motion, left and right motion, rotation, and gyro motion, etc. In addition, the vibration generator (not shown) may also apply vibration non-continuously or periodically. The vibration motor is a device that generates vibration by an eccentric rotation motion by connecting an eccentric axis to a rotational shaft of a motor, and is connected to the flat electrode 520 by a connection member.

The air knocker is a device that moves the piston forwards by the compressed air supplied into a housing and transfers an impact due to the forward movement of the piston to the flat electrode 520, thereby generating vibration in the horizontal electrode 520. The air knocker is arranged to face the flat electrode 520.

The electronic hammer is a device that includes an E-type core and an I-type core inside to generate vibration in the flat electrode 520 using an electromagnetic force generated between the E-type core and the I-type core when power is applied to the electronic hammer.

Furthermore, the plasma device for powder surface treatment using a horizontal electrode includes a controller (not shown) that adjusts the intensity of vibration applied to the flat electrode 520 by controlling the operation of the vibration generator (not shown) according to the amount of the powder put on the flat electrode 520.

The amount of the powder put on the flat electrode 520 may be measured from the amount of powder supplied from a powder supply unit (not shown). The vibration intensity of the vibration generator (not shown) may be set high as the amount of the powder put on the flat electrode 520 is increased.

When the plurality of flat electrodes 520 are stacked in the vertical direction, the flat electrodes 520 are spaced apart from each other by a preset minimum distance and the vibration intensity of the vibration generator (not shown) is set high above a certain intensity, when vibration is applied to the flat electrodes 520, the powder bouncing from the electrodes on the lower side among the flat electrodes 530 may be in contact with the surface of the electrodes on the upper side and may be surface-treated.

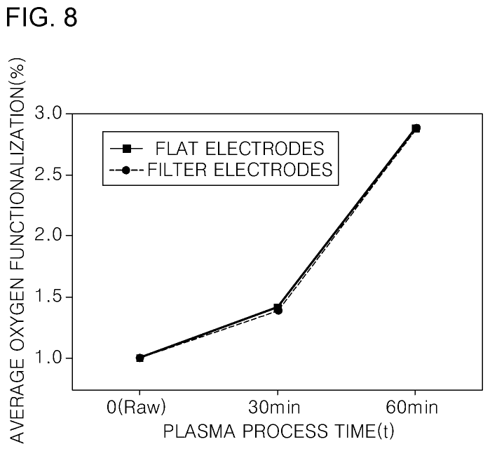

FIG. 8 is a graph for comparing oxygen functionalization in the case of a porous flat electrode with oxygen functionalization in the case of a non-porous flat electrode, respectively, when the powder is carbon nanotube and experiments on oxygen functionalization of the carbon nanotube are performed.

Referring to FIG. 8, it can be seen that the presence or absence of porosity has little effect on the oxygen functionalization of carbon nanotube.

Thus, when the flat electrode 520 is an aluminum flat plate that is not porous, the weight can be reduced, and manufacturing costs can be reduced compared to the case where a filter electrode is used.

In addition, when the non-porous flat electrode 520 is used as above, an additional adsorption unit is not required and thus, the device can be more compact, and costs can be reduced.

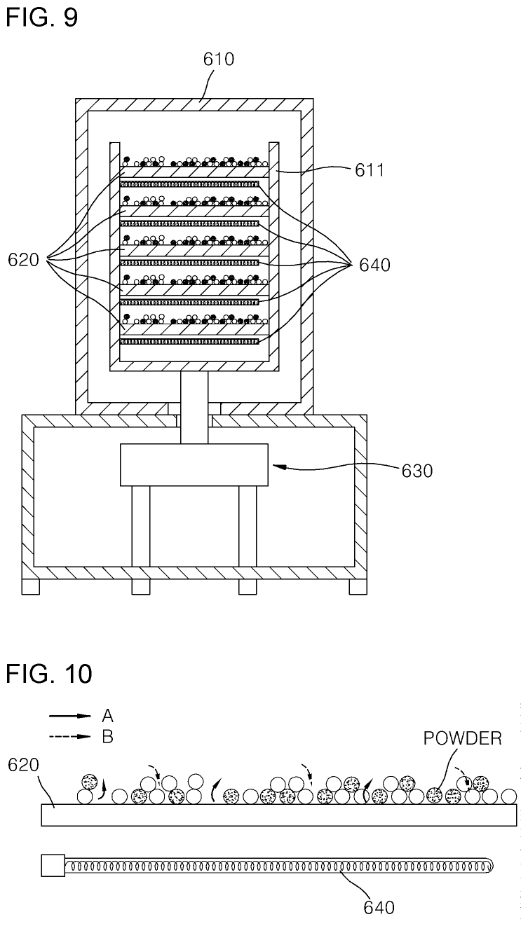

Meanwhile, FIG. 9 is a diagram schematically illustrating a plasma device for powder surface treatment using a horizontal electrode according to a sixth embodiment of the present invention. FIG. 10 is a diagram schematically illustrating the horizontal electrode shown in FIG. 9.

Referring to FIGS. 9 and 10, the plasma device for powder surface treatment using a horizontal electrode according to the sixth embodiment of the present invention includes a chamber 610, a horizontal electrode 620, a vibration generator 630, and a heater 640.

The powder includes nano- or micro-sized powder such as carbon nanotube, graphene or the like.

The horizontal electrode 620 is accommodated in the chamber 610, and the chamber 610 defines a space in which plasma is generated. A gas supply unit (not shown) that supplies external gas is connected to the chamber 610.

An example in which a rack 611 into which the horizontal electrode 620 is inserted, is provided inside the chamber 610, will be described.

The rack 611 may also be fixedly installed in the chamber 610 or may be installed to be picked out from the chamber 610 so that the rack 611 may also be brought into the chamber 610 after the horizontal electrode 620 is inserted into the rack 611.

The horizontal electrode 620 may be a power supply electrode to which power is supplied from the power supplying device (not shown). The horizontal electrode 620 generates plasma inside the chamber 610 when radio frequency (RF) power is applied from the power supplying device (not shown) and gas is supplied from the gas supply unit (not shown) into the chamber 610.

In the present embodiment, an example in which the chamber 610 or the rack 611 is a ground electrode, will be described. However, the present invention is not limited thereto, and the horizontal electrode 620 may also include an electrode having a potential difference between one side and the other side of the horizontal electrode 620 to generate plasma.

Plasma generated in the horizontal electrode 620 is used to functionalize the powder by surface treatment. Through surface functionalization of the powder, the powders are dispersed not to be aggregated without degradation of existing physical properties, and an interfacial bonding force between the powder and other heterogeneous materials can be enhanced.

The horizontal electrode 620 is arranged in the chamber 610 in the horizontal direction and has a flat plate shape so that the powder may be put on at least a part of the upper surface of the horizontal electrode 620. An example in which the horizontal electrode 620 has a rectangular plate shape, will be described.

However, the present invention is not limited thereto, and the horizontal electrode 620 may be variously changed and applicable when the horizontal electrode 620 has any shape on which the powder may be put, such as circular plate or bowl shapes. For example, as shown in FIG. 12, only at least a part of a horizontal electrode 620′ may also be flatly formed.

Moreover, the horizontal electrode 620 may be manufactured of various materials such as metal, polymer, ceramics and the like. The horizontal electrode 620 may also be manufactured of aluminum among metals, are lighter than other metals such as stainless and the like, and costs can be reduced.

The plurality of horizontal electrodes 620 are arranged to have separation spaces therebetween in the vertical direction or the horizontal direction. In the present embodiment, an example in which the plurality of horizontal electrodes 620 are inserted into the rack 611 to be spaced apart from each other by a certain distance in the vertical direction, will be described. The number of stacks of the horizontal electrodes 620 may be adjusted according to the volume of treatment.

The vibration generator 630 is a device that applies vibration to the horizontal electrode 620 and allows the position of the powders to be changed on the upper surface of the horizontal electrode 620 so that the powders can be uniformly surface-treated. The vibration generator 630 may generate vibration such as the effect of tapping the lower part of the horizontal electrode 620, thereby changing the position of powder located relatively closer to the surface of the horizontal electrode 620 and the position of powder located relatively further from the surface of the horizontal electrode 620. Thus, the powders put on the upper surface of the horizontal electrode 620 can be uniformly surface-treated. In the present embodiment, an example in which, when the vibration generator 630 is connected to the rack 611 and applies vibration to the rack 611, vibration is applied to the horizontal electrode 620 by vibration of the rack 611, will be described.

The vibration generator 630 may generate at least one of mechanical vibration, acoustic vibration, and ultrasonic vibration, thereby applying vibration to the horizontal electrode 620. In addition, the vibration generator 630 may apply vibration so that the horizontal electrode 620 may perform various behaviors such as up and down motion, left and right motion, rotation, and gyro motion, and the like. Furthermore, the vibration generator 630 may apply vibration discontinuously or periodically.

An example in which the vibration generator 630 generates mechanical vibration when power is applied to the vibration generator 630 by the power supplying device, will be described. However, the present invention is not limited thereto, and the vibration generator may also be an ultrasonic vibrator or an acoustic vibration module.

The vibration generator 630 includes a vibration motor (not shown) that applies vibration to the horizontal electrode 620 by a rotational force when power is applied to the vibration generator 630, an air knocker (not shown) that applies vibration to the horizontal electrode 620 by moving a piston by a compressed air, and an electronic hammer (not shown) that applies vibration to the horizontal electrode 620 using an electromagnetic force generated when power is applied to the electronic hammer (not shown). However, the present invention is not limited thereto, and the vibration generator 630 may apply vibration to the horizontal electrode 620 so that the horizontal electrode 620 may perform various behaviors such as up and down motion, left and right motion, rotation, and gyro motion, etc. Furthermore, the vibration generator 630 may also apply vibration non-continuously or periodically.

The vibration motor (not shown) is a device that generates vibration by an eccentric rotation motion by connecting an eccentric axis to a rotational shaft of a motor, and is connected to the horizontal electrode 620 by a connection member.

The air knocker (not shown) is a device that moves the piston forwards by the compressed air supplied into a housing and transfers an impact due to the forward movement of the piston to the horizontal electrode 620, thereby generating vibration in the horizontal electrode 620. The air knocker (not shown) is arranged to face the horizontal electrode 620.

The electronic hammer (not shown) is a device that includes an E-type core and an I-type core inside to generate vibration in the horizontal electrode 620 using an electromagnetic force generated between the E-type core and the I-type core when power is applied to the electronic hammer.

Meanwhile, the heater 640 is a device that heats the horizontal electrode 620 to remove residual moisture from the powders. Since, when the powder dispersed in a wet process is dried, a phenomenon in which moisture is lost by a capillary phenomenon and is re-aggregated, occurs, in the present embodiment, vibration is applied to the horizontal electrodes 620 by heating the horizontal electrode 620 and thus a state in which the powders are not aggregated and are dispersed, can be maintained. Thus, the powder dispersed in the wet process can be used in a dry process.

An example in which the heater 640 is an electrical heater, will be described, but the present invention is not limited thereto, and any type of heater 640 that may heat the horizontal electrode 620 may be variously changed and applicable.

An example, in which the heater 640 is arranged under each of the horizontal electrode 620, is spaced apart from the horizontal electrode 620 by a certain distance and is detachably coupled to the rack 611, will be described. In the present embodiment, an example in which the heater 640 is provided under each of the plurality of horizontal electrodes 620, will be described.

However, the present invention is not limited thereto, and as shown in FIG. 12, the heater 641 mounted under the horizontal electrode 620′ may also be used.

In addition, as shown in FIG. 13, a cylindrical lamp heater 642 arranged to surround the horizontal electrode 620′ may also be used. The lamp heater 642 may also have a cylindrical shape and may also have other shapes to surround the horizontal electrode 620′.

Moreover, the plasma device for powder surface treatment using a horizontal electrodes include a controller (not shown) that adjusts the intensity of vibration applied to the horizontal electrode 620 by controlling the operation of the vibration generator 630 according to the amount of the powder put on the horizontal electrode 620.

The controller (not shown) also controls the operation of the heater 640.

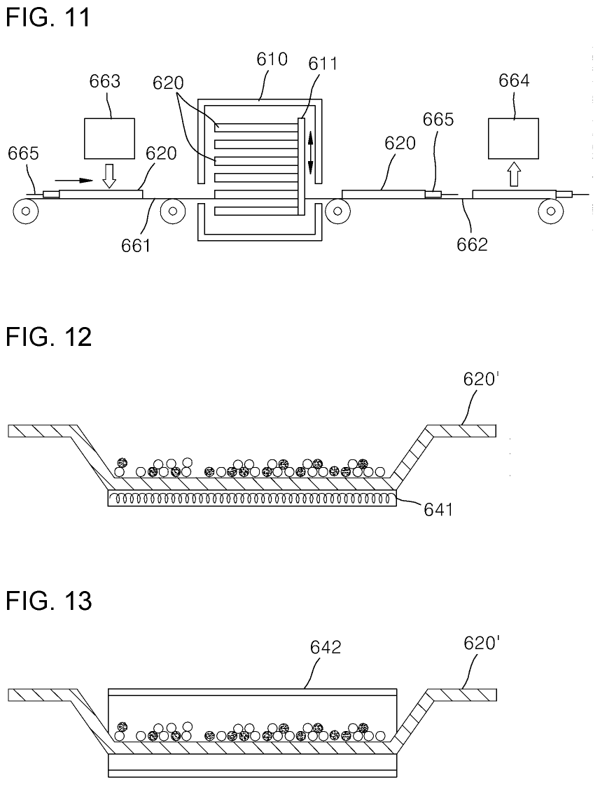

FIG. 11 is a diagram illustrating an example in which a plasma device for powder surface treatment using a horizontal electrode according to the sixth embodiment of the present invention is performed in a semi-continuous process.

Referring to FIG. 11, an example in which the plasma device for powder surface treatment is performed in a semi-continuous process, will be described, and the plasma device for powder surface treatment using a horizontal electrode further includes a loading conveyor 661, an unloading conveyor 662, a rack ascending/descending unit (not shown), a powder supply unit 663, and a powder collecting unit 664.

The loading conveyor 661 is a movement device that moves the horizontal electrodes 620 mounted on a movement jig 665 toward the inside of the chamber 610.

The unloading conveyor 662 is a movement device that picks out the horizontal electrode 620 on which powder surface treatment has been completed, from the chamber 610 and moves the horizontal electrode 620.

The rack ascending/descending unit (not shown) is a device that ascends or descends the horizontal electrode 620 on which the powder surface treatment has been completed, among the plurality of horizontal electrode 620 mounted on the rack 611 to the height of the unloading conveyor 662.

The powder supply unit 663 is a device that supplies the powders to the upper surface of the horizontal electrode 620. The powder supply unit 663 is separately provided from the chamber 610 and supplies the powders to the upper surface of the horizontal electrode 620 before the horizontal electrode 620 enters the chamber 610. That is, an example in which the powder supply unit 663 is provided at an upper side of the loading conveyor 661, will be described. However, the present invention is not limited thereto, and the powder supply unit 663 may be provided inside the chamber 610 and may also supply the powders to the upper surface of the horizontal electrode 620 in a state in which the horizontal electrode 620 is arranged in the chamber 610. In addition, the powder supply unit 663 may be arranged in each separation space between the plurality of horizontal electrodes 620 to spray the powders into the separation spaces at one time, and one powder sprayer (not shown) may be installed to be movable in the vertical direction to spray the powders into each separation space between the horizontal electors 620 continuously. Furthermore, the powder sprayer (not shown) may also spray the powder into the chamber 610.

The powder collecting unit 664 is a device that collects the powders that are powder surface-treated on the upper surface of the horizontal electrodes 620. The powder collecting unit 664 is provided separately from the chamber 610 and collects the powder from the horizontal electrodes 620 coming from the chamber 610. That is, an example in which the powder collecting unit 664 is provided on an upper side of the unloading conveyor 662, will be described. However, the present invention is not limited thereto, and the powder collecting unit 664 may also be provided in the chamber 610.

The operation of the plasma device for powder surface treatment using a horizontal electrode according to the sixth embodiment of the present invention having the above configuration will be described as below.

Referring to FIG. 11, when the horizontal electrode 620 is put on the loading conveyor 661, the powder supply unit 663 supplies the powder onto the upper surface of the horizontal electrodes 620.

The loading conveyor 661 moves the horizontal electrode 620 on which the powder is put, to the inside of the chamber 610.

The horizontal electrode 620 moved to the inside of the chamber 610 is inserted into the rack 611.

In this case, the rack ascending/descending unit (not shown) ascends or descends the horizontal electrode 620 so that an empty compartment of the rack 611 in which the horizontal electrode 620 are mounted, is located in a preset loading position. The loading position is pre-set to be identical to the height of the loading conveyor 661.

The horizontal electrode 620 is coupled to the rack 611 in a cartridge manner.

When the horizontal electrode 620 is coupled to the rack 611, the rack ascending/descending unit (not shown) returns the rack 611 to its original position where surface treatment is possible.

Subsequently, the vibration generator 630 and the heater 640 are activated.

When the vibration generator 630 is activated, vibration is applied to the horizontal electrode 620 through the rack 611.

When vibration is applied to the horizontal electrode 620, the position of the powder is changed on the upper surface of the horizontal electrode 620 by vibration and the powder may be uniformly surface-treated. That is, since the vibration generator 530 generates the effect of tapping the horizontal electrode 620, the position of powder located relatively closer to the surface of the horizontal electrode 620 and the position of powder located relatively further from the surface of the horizontal electrode 620 are repeatedly changed.

That is, referring to FIG. 10, an adsorption force B in a direction toward the surface of the horizontal electrode 620 and a dispersion force A in a direction bouncing from the surface of the horizontal electrode 620 outwardly act on the powders put on the horizontal electrode 620. In this case, the adsorption force B and the dispersion force A may be adjusted according to the vibration intensity of the vibration generator 630. The adsorption force B and the dispersion force A may be calculated as optimum values by experiments or the like. The adsorption force B and the dispersion force A are properly adjusted so that only the position movement of the powders is possible while the powders do not fly from the surface of the horizontal electrode 620 and thus the powders can be uniformly plasma surface-treated.

Thus, the powders may be dispersed while the position movement of the powders is performed in the vertical direction and the horizontal direction using the vibration generator 530, the powder can be prevented from being stacked above a certain thickness in a specific portion of the surface of the horizontal electrode 620.

In addition, since the effect of tapping the horizontal electrode 620 is given by the vibration generator 630, there is no need to completely remove the powders from the surface of the horizontal electrode 620, to float and disperse the powders and then to adsorb the powders and thus, a treatment time can be reduced compared to the case where the powder is floated, and the loss of the powder can be prevented.

Furthermore, since position movement is possible in a state in which the powders are adsorbed onto the surface of the horizontal electrodes 620, the powders can be uniformly surface-treated by plasma.

Moreover, when the heater 640 is activated, the residual moisture of the powders is removed so that reactivity can be increased.

That is, since a carbon nano-material such as carbon nanotube is sensitive to moisture, the residual moisture is removed during plasma surface treatment so that surface treatment efficiency can be enhanced.

In the present invention, since vibration is applied while the horizontal electrode 620 is heated, a state in which the powder is dried and dispersed, can be maintained. That is, when the powders are only dried, side effects in which water is lost by a capillary phenomenon and a material is re-aggregated again, may occur, but vibration is applied to the horizontal electrode 620 while the horizontal electrode 620 are heated, so that the powder can be uniformly dispersed without being aggregated. Thus, the powder dispersed by the wet process can be applied to the dry process.

The process in which the powder is surface-treated by plasma, may be performed for a preset time.

When there is the horizontal electrode 620 on which surface treatment has been completed, among the plurality of horizontal electrodes 620 mounted on the rack 611, the rack ascending/descending unit (not shown) moves the horizontal electrode 620 on which surface treatment has been completed, to a preset unloading position. The unloading position is pre-set to the height of the unloading conveyor 662.

The horizontal electrode 620 on which surface treatment has been completed, is picked out from the rack 611 by the movement jig 665.

The unloading conveyor 662 moves the horizontal electrode 610 picked out from the rack 611 to an outside of the chamber 610.

The powder collecting unit 664 collects the powders surface-treated on the surface of the horizontal electrodes 620.

The horizontal electrodes 620 from which the powders are collected, are moved to the loading conveyor 661 and are re-loaded.

As described above, since the plasma device for powder surface treatment using a horizontal electrode according to the present invention has a structure in which the plurality of horizontal electrodes 620 are stacked, the structure is very simple, and the volume that can be treated at one time can be maximized according to the number of stacks of the horizontal electrodes 620.

Furthermore, since surface treatment is performed in a state in which the powders are put on the upper surface of the horizontal electrodes 620, the powders that are not treated but are discarded can be minimized compared to the case where the powders are floated and then are adsorbed. Moreover, a process of repeatedly performing completely removing the powders from the surface of the horizontal electrode 620 and floating and dispersing the powders is not required so that treatment efficiency can be enhanced.

In addition, vibration is applied to the horizontal electrode 620 using the vibration generator 630 so that the adsorption force B at which the power is adsorbed onto the surface of the horizontal electrode 620 and the dispersion force A at which the powders are removed from the horizontal electrode 620, can be properly adjusted and thus the position movement of the powders is possible while the powders do not fly from the surface of the horizontal electrode 620 and the powders can be uniformly plasma surface-treated.

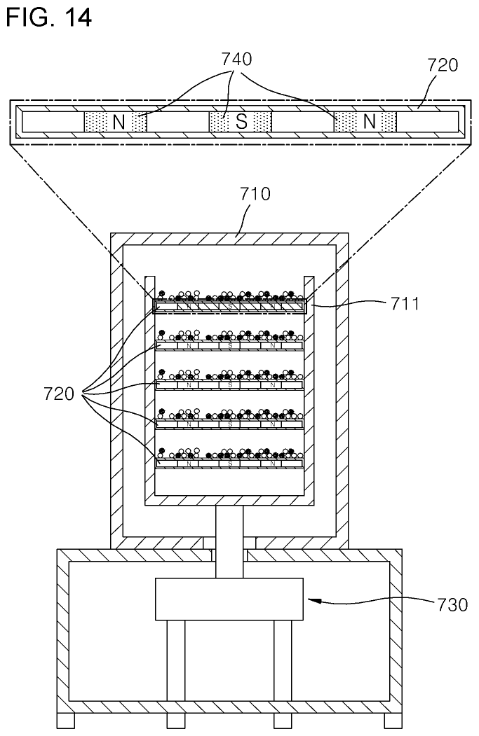

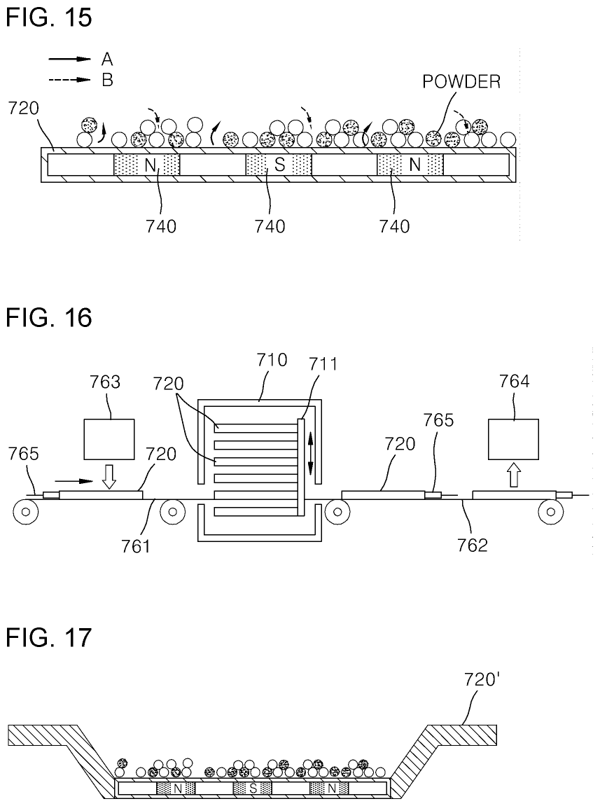

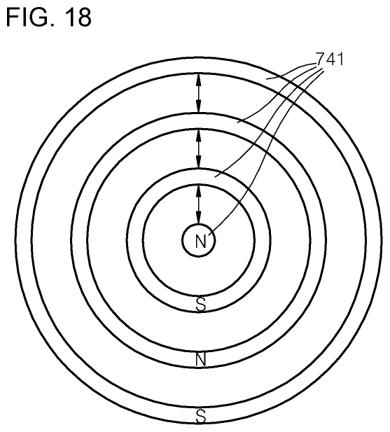

Meanwhile, FIG. 14 is a diagram schematically illustrating a plasma device for powder surface treatment using a horizontal electrode according to a seventh embodiment of the present invention. FIG. 15 is a diagram schematically illustrating the horizontal electrode shown in FIG. 14.

Referring to FIGS. 14 and 15, the plasma device for powder surface treatment using a horizontal electrode according to the seventh embodiment of the present invention includes a chamber 710, a horizontal electrode 720, a vibration generator 730, and a magnetic force generator 740.

The powder includes nano- or micro-sized powder such as carbon nanotube, graphene or the like.

The horizontal electrode 720 is accommodated in the chamber 710, and the chamber 710 defines a space in which plasma is generated. A gas supply unit (not shown) that supplies external gas is connected to the chamber 710.

An example in which a rack 711 into which the horizontal electrode 720 is inserted, is provided inside the chamber 710, will be described.

The rack 711 may also be fixedly installed in the chamber 710 or may be installed to be picked out from the chamber 710 so that the rack 711 may also be brought into the chamber 710 after the horizontal electrode 720 is inserted into the rack 711.

The horizontal electrode 720 may be a power supply electrode to which power is supplied from the power supplying device (not shown). The horizontal electrode 720 generates plasma inside the chamber 710 when RF power is applied from the power supplying device (not shown) and gas is supplied from the gas supply unit (not shown) into the chamber 710.

In the present embodiment, an example in which the chamber 710 or the rack 711 is a ground electrode, will be described. However, the present invention is not limited thereto, and the horizontal electrode 720 may also include an electrode having a potential difference between one side and the other side of the horizontal electrode 720 to generate plasma.

Plasma generated in the horizontal electrode 720 is used to functionalize the powder by surface treatment. Through surface functionalization of the powder, the powders are dispersed not to be aggregated without degradation of existing physical properties, and an interfacial bonding force between the powder and other heterogeneous materials can be enhanced.

The horizontal electrode 720 is arranged in the chamber 710 in the horizontal direction and has a flat plate shape so that the powder may be put on at least a part of the upper surface of the horizontal electrode 720.

However, the present invention is not limited thereto, and the horizontal electrode 720 may be variously changed and applicable when the horizontal electrode 720 has any shape on which the powder may be put, such as circular plate or bowl shapes. For example, as shown in FIG. 17, only at least a part of a horizontal electrode 720′ may also be flatly formed.

Moreover, the horizontal electrode 720 may be manufactured of various materials such as metal, polymer, ceramics and the like. The horizontal electrode 720 may also be manufactured of aluminum among metals and is lighter than other metals such as stainless and the like, and costs may be reduced.

The plurality of horizontal electrodes 720 are stacked in the vertical direction or the horizontal direction and are arranged to have separation spaces therebetween. In the present embodiment, an example in which the plurality of horizontal electrodes 720 are inserted into the rack 711 to be spaced apart from each other by a certain distance in the vertical direction, will be described. The number of stacks of the horizontal electrodes 720 may be adjusted according to the volume of treatment.

The vibration generator 730 is a device that applies vibration to the horizontal electrode 720 and allows the position of the powders to be changed on the upper surface of the horizontal electrode 720 so that the powders can be uniformly surface-treated. The vibration generator 730 may generate vibration such as the effect of tapping the lower part of the horizontal electrode 720, thereby changing the position of powder located relatively closer to the surface of the horizontal electrode 720 and the position of powder located relatively further from the surface of the horizontal electrode 720. Thus, the powders put on the upper surface of the horizontal electrodes 720 can be uniformly surface-treated. In the present embodiment, an example in which, when the vibration generator 730 is connected to the rack 711 and applies vibration to the rack 711, vibration is applied to the horizontal electrode 720 by vibration of the rack 711, will be described.

The vibration generator 730 may generate at least one of mechanical vibration, acoustic vibration, and ultrasonic vibration, thereby applying vibration to the horizontal electrode 720. Moreover, the vibration generator 730 may apply vibration so that the horizontal electrode 720 may perform various behaviors such as up and down motion, left and right motion, rotation, and gyro motion, and the like. In addition, the vibration generator 730 may apply vibration discontinuously or periodically.

An example in which the vibration generator 730 generates mechanical vibration when power is applied to the vibration generator 730 by the power supplying device, will be described. However, the present invention is not limited thereto, and the vibration generator may also be an ultrasonic vibrator or an acoustic vibration module.

The vibration generator 730 includes a vibration motor (not shown) that applies vibration to the horizontal electrode 720 by a rotational force when power is applied to the vibration generator 730, an air knocker (not shown) that applies vibration to the horizontal electrode 720 by moving a piston by a compressed air, and an electronic hammer (not shown) that applies vibration to the horizontal electrode 720 using an electromagnetic force generated when power is applied to the electronic hammer (not shown). However, the present invention is not limited thereto, and the vibration generator 730 may apply vibration to the horizontal electrode 720 so that the horizontal electrode 720 may perform various behaviors such as up and down motion, left and right motion, rotation, and gyro motion, etc. In addition, the vibration generator 730 may also apply vibration non-continuously or periodically.

The vibration motor (not shown) is a device that generates vibration by an eccentric rotation motion by connecting an eccentric axis to a rotational shaft of a motor, and is connected to the horizontal electrode 720 by a connection member.

The air knocker (not shown) is a device that moves the piston forwards by the compressed air supplied into a housing and transfers an impact due to the forward movement of the piston to the horizontal electrode 720, thereby generating vibration in the horizontal electrode 720. The air knocker (not shown) is arranged to face the horizontal electrode 720.

The electronic hammer (not shown) is a device that includes an E-type core and an I-type core inside to generate vibration in the horizontal electrode 720 using an electromagnetic force generated between the E-type core and the I-type core when power is applied to the electronic hammer.

Meanwhile, the magnetic force generator 740 is a device that generates a magnetic force in the periphery of the horizontal electrode 720 to generate additional movement of electrons so that plasma density can be increased.

The magnetic force generator 740 includes at least one or more magnets having different polarities, and the plurality of magnets are arranged to be spaced apart from each other by a certain distance. The shape or arrangement of the magnets are variously changed and applicable, and it is preferable that magnetic forces are uniformly formed in the periphery of the horizontal electrode 720 so that plasma density can be uniformly generated.

In the present embodiment, an example in which the magnetic force generator 740 is a magnet inserted into the horizontal electrode 720, will be described. However, the present invention is not limited thereto, and the magnetic force generator 740 may also be mounted on the horizontal electrode 720. Moreover, the magnetic force generator 740 may also be an electromagnet.

At least a part of the horizontal electrode 720 has a magnet insertion unit 720a into which the magnetic force generator 740 may be inserted.

In addition, the plasma device for powder surface treatment using a horizontal electrode includes a controller (not shown) that adjusts the intensity of vibration applied to the horizontal electrode 720 by controlling the operation of the vibration generator 730 according to the amount of the powder put on the horizontal electrode 720.

FIG. 16 is a diagram illustrating an example in which a plasma device for powder surface treatment using a horizontal electrode according to the seventh embodiment of the present invention is performed in a semi-continuous process.

Referring to FIG. 16, an example in which the plasma device for powder surface treatment using a horizontal electrode is performed in a semi-continuous process, will be described, and the plasma device for powder surface treatment using a horizontal electrode further includes a loading conveyor 761, an unloading conveyor 762, a rack ascending/descending unit (not shown), a powder supply unit 763, and a powder collecting unit 764.

The loading conveyor 761 is a moving device that moves the horizontal electrode 720 mounted on the movement jig 765 to the inside of the chamber 710.

The unloading conveyor 762 is a moving device that picks out the horizontal electrode 720 on which powder surface treatment has been completed, from the chamber 710 and moves the horizontal electrode 720.

The rack ascending/descending unit (not shown) is a device that ascends or descends the horizontal electrode 720 on which the powder surface treatment has been completed among the plurality of horizontal electrodes 720 mounted on the rack 711 to the height of the unloading conveyor 762.

The powder supply unit 763 is a device that supplies the powders onto the upper surface of the horizontal electrode 720. The powder supply unit 763 is provided separately from the chamber 710, and supplies the powders onto the upper surface of the horizontal electrode 720 before the horizontal electrode 720 enters the chamber 710. That is, an example in which the powder supply unit 763 is provided on the upper side of the loading conveyor 761, will be described. However, the present invention is not limited thereto, and the powder supply unit 763 is provided inside the chamber 710, and the powders may also be supplied onto the upper surface of the horizontal electrode 720 in a state in which the horizontal electrode 720 is arranged in the chamber 710. Moreover, the powder supply unit 763 may be arranged in each separation space between the plurality of horizontal electrodes 720 and may also spray the powders into the separation spaces at one time, and one powder sprayer (not shown) may be installed to be movable in the vertical direction and may also spray the powders in each separation space between the horizontal electrodes 720. In addition, the powder sprayer (not shown) may also spray the powder into the chamber 710.

The powder collecting unit 764 is a device that collects the powders that are powder surface-treated on the upper surface of the horizontal electrode 720. The powder collecting unit 764 is provided separately from the chamber 710 and collects the powder from the horizontal electrode 729 coming from the chamber 710. That is, an example in which the powder collecting unit 764 is provided on the upper side of the unloading conveyor 762, will be described. However, the present invention is not limited thereto, and the powder collecting unit 764 may also be provided in the chamber 710.

The operation of the plasma device for powder surface treatment using a horizontal electrode according to the seventh embodiment of the present invention having the above configuration will be described.

Referring to FIG. 16, when the horizontal electrode 720 is put on the loading conveyor 761, the powder supply unit 763 supplies the powder onto the upper surface of the horizontal electrode 720.

The loading conveyor 761 moves the horizontal electrode 720 on which the powder is put, to the inside of the chamber 710.

The horizontal electrode 720 moved to the inside of the chamber 710 is inserted into the rack 711.

In this case, the rack ascending/descending unit (not shown) ascends or descends the horizontal electrode 720 so that an empty compartment of the rack 711 in which the horizontal electrode 720 is mounted, is located in a preset loading position. The loading position is pre-set to be identical to the height of the loading conveyor 761.

The horizontal electrode 720 is coupled to the rack 711 in a cartridge manner.

When the horizontal electrode 720 is coupled to the rack 711, the rack ascending/descending unit (not shown) returns the rack 711 to its original position where surface treatment is possible.

Subsequently, the vibration generator 730 is activated.

When the vibration generator 730 is activated, vibration is applied to the horizontal electrode 720 through the rack 711.

When vibration is applied to the horizontal electrode 720, the position of the powders is changed on the upper surface of the horizontal electrode 720 by vibration, and the powders may be uniformly surface-treated. That is, since the vibration generator 730 generates the effect of tapping the horizontal electrode 720, the position of powder located relatively closer to the surface of the horizontal electrodes 720 and the position of powder located relatively further from the surface of the horizontal electrodes 720 are repeatedly changed.

That is, referring to FIG. 15, an adsorption force B in a direction toward the surface of the horizontal electrode 720 and a dispersion force A in a direction bouncing from the surface of the horizontal electrode 720 outwardly act on the powders put on the horizontal electrode 720. In this case, the adsorption force B and the dispersion force A may be adjusted according to the vibration intensity of the vibration generator 730. The adsorption force B and the dispersion force A may be calculated as optimum values by experiments or the like. The adsorption force B and the dispersion force A are properly adjusted so that only the position movement of the powder is possible while the powders do not fly from the surface of the horizontal electrode 720 and thus the powders can be uniformly plasma surface-treated.

Thus, the powders may be dispersed while the position movement of the powders is performed in the vertical direction and the horizontal direction using the vibration generator 730, the powder can be prevented from being stacked above a certain thickness in a specific portion of the surface of the horizontal electrode 720.

In addition, since the effect of tapping the horizontal electrode 720 is given by the vibration generator 730, there is no need to completely remove the powders from the surface of the horizontal electrode 720, to float and disperse the powders and then to adsorb the powders and thus, a treatment time can be reduced compared to the case where the powders are floated, and the loss of the powders can be prevented.

Moreover, since position movement is possible in a state in which the powders are adsorbed onto the surface of the horizontal electrode 720, the powders can be uniformly surface-treated by plasma.

In addition, when a magnetic force is generated in the periphery of the horizontal electrode 720 by the magnetic force generator 740, an additional movement of electron is generated so that plasma density can be increased and surface treatment speed can be enhanced.

The process in which the powder is surface-treated by plasma, may be performed for a preset time.

When there is the horizontal electrode 720 on which surface treatment has been completed, among the plurality of horizontal electrodes 720 mounted on the rack 711, the rack ascending/descending unit (not shown) moves the horizontal electrode 720 on which surface treatment has been completed, to a preset unloading position. The unloading position is pre-set to the height of the unloading conveyor 662.

The horizontal electrode 720 on which surface treatment has been completed, is picked out from the rack 711 by the movement jig 765.

The unloading conveyor 762 moves the horizontal electrodes 720 picked out from the rack 711 to an outside of the chamber 710.

The powder collecting unit 764 collects the powders surface-treated on the surface of the horizontal electrode 720.

The horizontal electrode 720 from which the powders are collected, is moved to the loading conveyor 761 and is re-loaded.

As described above, since the plasma device for powder surface treatment using a horizontal electrode according to the present invention has a structure in which the plurality of horizontal electrodes 720 are stacked, the structure is very simple, and the volume that can be treated at one time can be maximized according to the number of stacks of the horizontal electrodes 720.

Moreover, since surface treatment is performed in a state in which the powders are put on the upper surface of the horizontal electrode 720, the powders that are not treated but are discarded can be minimized compared to the case where the powders are floated and then are adsorbed. In addition, a process of repeatedly performing completely removing the powder from the surface of the horizontal electrode 720 and floating and dispersing the powder is not required so that treatment efficiency can be enhanced.

Moreover, vibration is applied to the horizontal electrode 720 using the vibration generator 730 so that the adsorption force B at which the powder is adsorbed onto the surface of the horizontal electrode 720 and the dispersion force A at which the powder is removed from the horizontal electrode 720, can be properly adjusted and thus the position movement of the powders is possible while the powders do not fly from the surface of the horizontal electrode 720 and the powders can be uniformly plasma surface-treated.

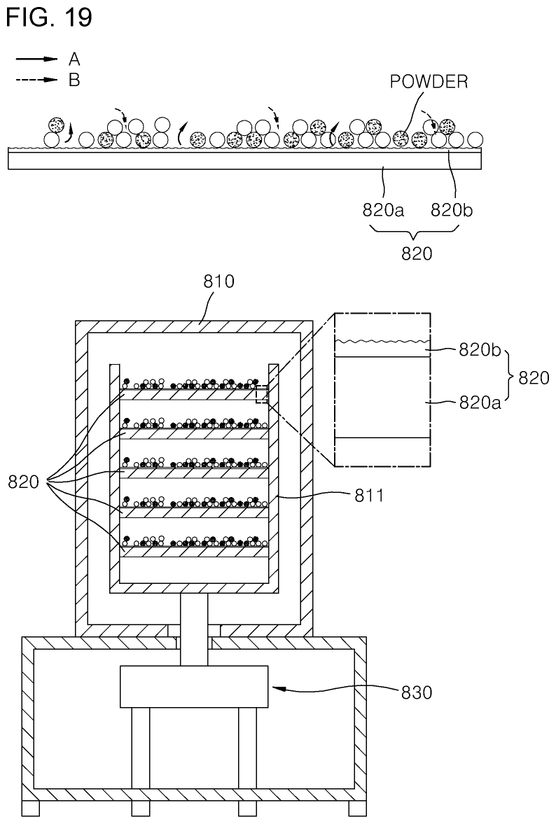

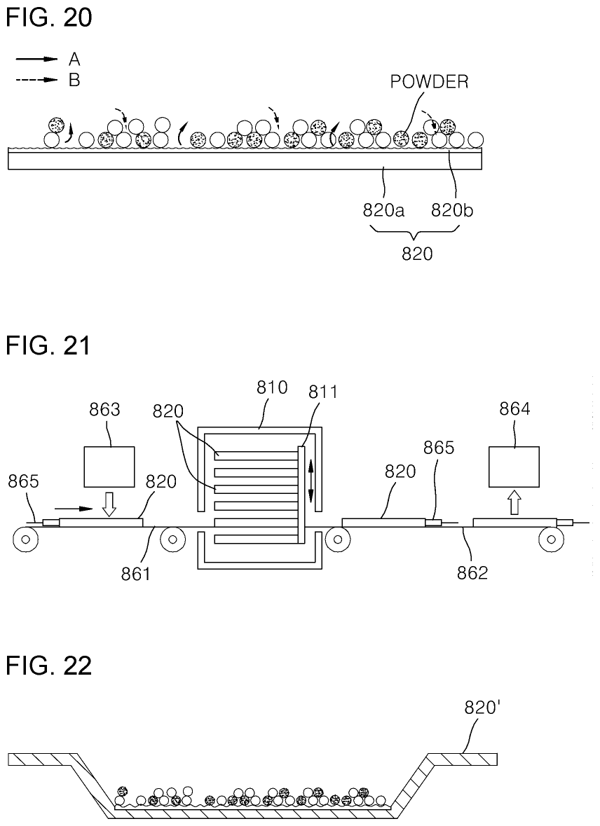

Meanwhile, FIG. 19 is a diagram schematically illustrating a plasma device for powder surface treatment using a horizontal electrode according to an eighth embodiment of the present invention. FIG. 20 is a diagram schematically illustrating the horizontal electrode shown in FIG. 19.

Referring to FIGS. 19 and 20, the plasma device for powder surface treatment using a horizontal electrode according to the eighth embodiment of the present invention includes a chamber 810, a horizontal electrode 820, and a vibration generator 830.

The powder includes nano-sized or micro-sized powder such as carbon nanotube, graphene, etc.

The horizontal electrode 820 is accommodated in the chamber 810, and the chamber 810 defines a space in which plasma is generated. A gas supply unit (not shown) that supplies external gas is connected to the chamber 810.

An example in which a rack 811 into which the horizontal electrode 820 is inserted, is provided in the chamber 810, will be described.

The rack 811 may also be fixedly installed in the chamber 810 or may be installed to be picked out from the chamber 810 so that the rack 811 may also be brought into the chamber 810 after the horizontal electrode 820 is inserted into the rack 811.

The filter electrode 820 may be a power supply electrode to which power is supplied from the power supplying device (not shown). The filter electrode 820 generates plasma inside the chamber 810 when power is applied from the power supplying device (not shown) and gas is supplied from the gas supply unit (not shown) into the chamber 810.

In the present embodiment, an example in which the chamber 810 is a ground electrode, will be described, but the present invention is not limited thereto, and the horizontal electrode 820 may also include an electrode having a potential difference between one side and the other side of the horizontal electrode 820 to generate plasma.

Plasma generated in the horizontal electrode 820 is used to functionalize the powder by surface treatment. Through surface functionalization of the powder, the powders are dispersed not to be aggregated without degradation of existing physical properties, and an interfacial bonding force between the powder and other heterogeneous materials can be enhanced.

The horizontal electrode 820 is arranged in the chamber 810 in the horizontal direction and has a flat plate shape so that the powder may be put on the upper surface of the horizontal electrode 820.

However, the present invention is not limited thereto, and the horizontal electrode 820 having any shape in which the powder may be put, such as a circular plate, bowl shape, or the like, may be variously changed and applicable. For example, as shown in FIG. 22, only at least a part of a horizontal electrode 820′ may also be flatly formed.

In addition, the horizontal electrode 820 may be manufactured of various materials such as metal, polymer, ceramics, etc. The horizontal electrode 820 may also be manufactured of aluminum among metals so that the horizontal electrode 820 are lighter than other metals such as stainless, etc. and costs can be reduced.

At least a part of the upper surface of the horizontal electrode 820 is textured with a preset texture pattern so as to have preset surface roughness. When the texture pattern is formed on a portion on which the powders are put, of the upper surface of the horizontal electrode 820, the powder may collide with the texture pattern when the horizontal electrode 820 vibrates, and mechanical energy may be additionally used so that the efficiency of plasma surface treatment can be increased.

The horizontal electrode 820 includes a base material 820a, and a pattern layer 820b in which the texture pattern is formed.

An example in which the base material 820a is formed of an aluminum material, will be described.

The pattern layer 820b is a layer in which the texture pattern is formed by oxidizing at least a part of the surface of the base material 820a by anodization so that the texture pattern is formed. However, the present invention is not limited thereto, and the pattern layer 820b may also be formed by processing such as milling or the like.

Moreover, the plurality of horizontal electrodes 820 are stacked in the vertical direction or the horizontal direction and are arranged to have separation spaces therebetween. In the present embodiment, an example in which the plurality of horizontal electrodes 820 are inserted into the rack 811 to be spaced apart from each other by a certain distance in the vertical direction, will be described. The number of stacks of the horizontal electrodes 820 may be adjusted according to the volume of treatment.

The vibration generator 830 is a device that applies vibration to the horizontal electrode 820 and allows the position of the powders to be changed on the upper surface of the horizontal electrode 820 so that the powders can be uniformly surface-treated. The vibration generator 830 may generate vibration such as the effect of tapping the lower part of the horizontal electrode 820, thereby changing the position of powder located relatively closer to the surface of the horizontal electrodes 820 and the position of powder located relatively further from the surface of the horizontal electrodes 820. Thus, the powders put on the upper surface of the horizontal electrodes 820 may be uniformly surface-treated. In the present embodiment, an example in which, when the vibration generator 830 is connected to the rack 811 and applies vibration to the rack 811, vibration is applied to the horizontal electrode 820 by vibration of the rack 811, will be described.

The vibration generator 830 may generate at least one of mechanical vibration, acoustic vibration, and ultrasonic vibration, thereby applying vibration to the horizontal electrode 820. In addition, the vibration generator 830 may apply vibration so that the horizontal electrode 820 may perform various behaviors such as up and down motion, left and right motion, rotation, and gyro motion, and the like. Furthermore, the vibration generator 830 may apply vibration discontinuously or periodically.

An example in which the vibration generator 830 generates mechanical vibration when power is applied to the vibration generator 830 by the power supplying device, will be described. However, the present invention is not limited thereto, and the vibration generator may also be an ultrasonic vibrator or an acoustic vibration module.

The vibration generator 830 includes a vibration motor (not shown) that applies vibration to the horizontal electrode 820 by a rotational force when power is applied to the vibration generator 830, an air knocker (not shown) that applies vibration to the horizontal electrode 820 by moving a piston by a compressed air, and an electronic hammer (not shown) that applies vibration to the horizontal electrode 820 using an electromagnetic force generated when power is applied to the electronic hammer (not shown). However, the present invention is not limited thereto, and the vibration generator 830 may apply vibration to the horizontal electrode 820 so that the horizontal electrode 820 may perform various behaviors such as up and down motion, left and right motion, rotation, and gyro motion, etc. Moreover, the vibration generator 830 may also apply vibration non-continuously or periodically.

The vibration motor (not shown) is a device that generates vibration by an eccentric rotation motion by connecting an eccentric axis to a rotational shaft of a motor, and is connected to the horizontal electrode 820 by a connection member.

The air knocker (not shown) is a device that moves the piston forwards by the compressed air supplied into a housing and transfers an impact due to the forward movement of the piston to the horizontal electrode 820, thereby generating vibration in the horizontal electrode 820. The air knocker (not shown) is arranged to face the horizontal electrode 820.

The electronic hammer (not shown) is a device that includes an E-type core and an I-type core inside to generate vibration in the horizontal electrode 820 using an electromagnetic force generated between the E-type core and the I-type core when power is applied to the electronic hammer.

Furthermore, the plasma device for powder surface treatment using a horizontal electrode includes a controller (not shown) that adjusts the intensity of vibration applied to the horizontal electrode 820 by controlling the operation of the vibration generator 830 according to the amount of the powder put on the horizontal electrode 820.

FIG. 21 is a diagram illustrating an example in which the plasma device for powder surface treatment using a horizontal electrode according to the eighth embodiment of the present invention is performed in a semi-continuous process.

Referring to FIG. 21, an example in which the plasma device for powder surface treatment is performed in a semi-continuous process, will be described, and the plasma device for powder surface treatment using a horizontal electrode further includes a loading conveyor 861, an unloading conveyor 862, a rack ascending/descending unit (not shown), a powder supply unit 863, and a powder collecting unit 864.

The loading conveyor 861 is a movement device that moves the horizontal electrode 820 mounted on a movement jig 865 toward the inside of the chamber 810.

The unloading conveyor 862 is a movement device that picks out the horizontal electrode 820 on which powder surface treatment has been completed, from the chamber 810 and moves the horizontal electrode 820.

The rack ascending/descending unit (not shown) is a device that ascends or descends the horizontal electrode 820 on which the powder surface treatment has been completed among the plurality of horizontal electrode 820 mounted on the rack 811 to the height of the unloading conveyor 862.

The powder supply unit 863 is a device that supplies the powder to the upper surface of the horizontal electrode 820. The powder supply unit 863 is separately provided from the chamber 810 and supplies the powder to the upper surface of the horizontal electrode 820 before the horizontal electrode 820 enter the chamber 810. That is, an example in which the powder supply unit 863 is provided at an upper side of the loading conveyor 861, will be described. However, the present invention is not limited thereto, and the powder supply unit 863 may be provided inside the chamber 810 and may also supply the powder to the upper surface of the horizontal electrode 820 in a state in which the horizontal electrode 820 is arranged in the chamber 810. In addition, the powder supply unit 863 may be arranged in each separation space between the plurality of horizontal electrodes 820 to spray the powders into the separation spaces at one time, and one powder sprayer (not shown) may be installed to be movable in the vertical direction to spray the powders into each separation space between the horizontal electrodes 820 continuously. Moreover, the powder sprayer (not shown) may also spray the powder into the chamber 810.

The powder collecting unit 864 is a device that collects the powders that are powder surface-treated on the upper surface of the horizontal electrode 820. The powder collecting unit 864 is provided separately from the chamber 810 and collects the powder from the horizontal electrodes 820 coming from the chamber 810. That is, an example in which the powder collecting unit 864 is provided on an upper side of the unloading conveyor 862, will be described. However, the present invention is not limited thereto, and the powder collecting unit 864 may also be provided in the chamber 810.

The operation of the plasma device for powder surface treatment using a horizontal electrode according to the eighth embodiment of the present invention having the above configuration will be described as below.

Referring to FIG. 21, when the horizontal electrode 820 is put on the loading conveyor 861, the powder supply unit 863 supplies the powder onto the upper surface of the horizontal electrode 820.

The loading conveyor 861 moves the horizontal electrode 820 on which the powder is put, to the inside of the chamber 810.

The horizontal electrode 820 moved to the inside of the chamber 810 is inserted into the rack 811.

In this case, the rack ascending/descending unit (not shown) ascends or descends the horizontal electrode 820 so that an empty compartment of the rack 811 in which the horizontal electrode 820 is mounted, is located in a preset loading position. The loading position is pre-set to be identical to the height of the loading conveyor 861.

The horizontal electrode 820 is coupled to the rack 811 in a cartridge manner.

When the horizontal electrode 820 is coupled to the rack 811, the rack ascending/descending unit (not shown) returns the rack 811 to its original position where surface treatment is possible.

Subsequently, the vibration generator 830 and the heater 840 are activated.

When the vibration generator 830 is activated, vibration is applied to the horizontal electrode 820 through the rack 811.

When vibration is applied to the horizontal electrode 820, the position of the powder is changed on the upper surface of the horizontal electrode 820 by vibration and the powders may be uniformly surface-treated. That is, since the vibration generator 830 generates the effect of tapping the horizontal electrode 820, the position of powder located relatively closer to the surface of the horizontal electrode 820 and the position of powder located relatively further from the surface of the horizontal electrode 820 are repeatedly changed.

That is, referring to FIG. 20, an adsorption force B in a direction toward the surface of the horizontal electrode 820 and a dispersion force A in a direction bouncing from the surface of the horizontal electrode 820 outwardly act on the powders put on the horizontal electrode 820. In this case, the adsorption force B and the dispersion force A may be adjusted according to the vibration intensity of the vibration generator 830. The adsorption force B and the dispersion force A may be calculated as optimum values by experiments or the like. The adsorption force B and the dispersion force A are properly adjusted so that only the position movement of the powders is possible while the powders do not fly from the surface of the horizontal electrode 820 and thus the powders can be uniformly plasma surface-treated.

Thus, the powders may be dispersed while the position movement of the powder is performed in the vertical direction and the horizontal direction using the vibration generator 830, the powder can be prevented from being stacked above a certain thickness in a specific portion of the surface of the horizontal electrode 820.

Furthermore, since the effect of tapping the horizontal electrode 820 is given by the vibration generator 830, there is no need to completely remove the powders from the surface of the horizontal electrode 820, to float and disperse the powders and then to adsorb the powders and thus, a treatment time can be reduced compared to the case where the powder is floated, and the loss of the powder can be prevented.

In addition, since position movement is possible in a state in which the powders are adsorbed onto the surface of the horizontal electrode 820, the powders can be uniformly surface-treated by plasma.

Furthermore, the texture pattern is formed on the horizontal electrode 820 so that, when the powders are moved by vibration of the horizontal electrode 820, the powders may collide with the pattern layer 820b so that the effect of plasma treatment can be enhanced.

The process in which the powder is surface-treated by plasma, may be performed for a preset time.

When there is the horizontal electrode 820 on which surface treatment has been completed, among the plurality of horizontal electrodes 820 mounted on the rack 811, the rack ascending/descending unit (not shown) moves the horizontal electrode 820 on which surface treatment has been completed, to a preset unloading position. The unloading position is pre-set to the height of the unloading conveyor 862.

The horizontal electrode 820 on which surface treatment has been completed, is picked out from the rack 811 by the movement jig 865.

The unloading conveyor 862 moves the horizontal electrode 820 picked out from the rack 811 to an outside of the chamber 810.

The powder collecting unit 864 collects the powders that are powder surface-treated on the surface of the horizontal electrodes 820.

The horizontal electrode 820 from which the powders are collected, are moved to the loading conveyor 861 and are re-loaded.

As described above, since the plasma device for powder surface treatment using a horizontal electrode according to the present invention has a structure in which the plurality of horizontal electrodes 820 are stacked, the structure is very simple, and the volume that can be treated at one time can be maximized according to the number of stacks of the horizontal electrodes 820.

Moreover, since surface treatment is performed in a state in which the powders are put on the upper surface of the horizontal electrode 820, the powders that are not treated but are discarded can be minimized compared to the case where the powders are floated and then are adsorbed. In addition, a process of repeatedly performing completely removing the powder from the surface of the horizontal electrode 820 and floating and dispersing the powder is not required so that treatment efficiency can be enhanced.

Furthermore, vibration is applied to the horizontal electrode 820 using the vibration generator 830 so that the adsorption force B at which the powder is adsorbed onto the surface of the horizontal electrode 820 and the dispersion force A at which the powder is removed from the horizontal electrode 820, can be properly adjusted and thus the position movement of the powders is possible while the powders do not fly from the surface of the horizontal electrode 820 and the powders can be uniformly plasma surface-treated.

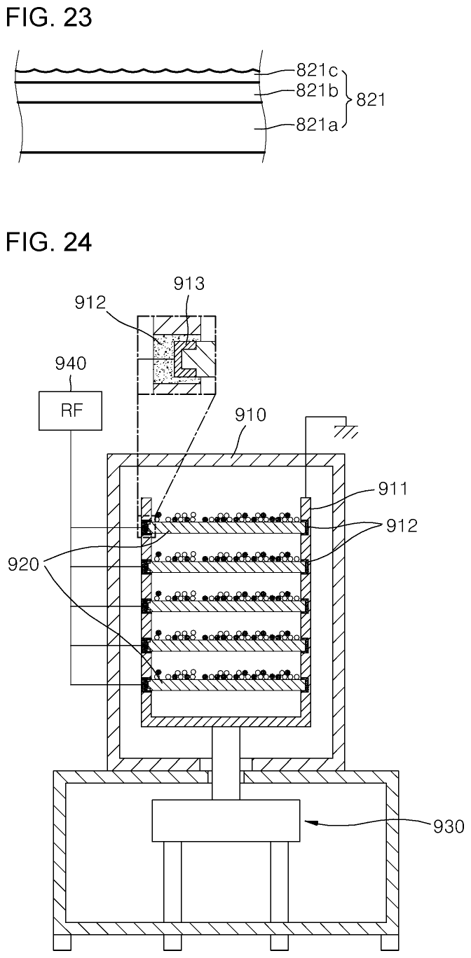

Meanwhile, FIG. 23 is a diagram schematically illustrating another example of a plasma device for powder surface treatment using a horizontal electrode according to the eighth embodiment of the present invention.

Referring to FIG. 23, a horizontal electrode 821 may also include a base material 821a formed of a metal material, a coating layer 821b formed by coating an aluminum material on the surface of the base material 821a, and a pattern layer 821c having the texture pattern formed by oxidizing at least a part of the surface of the coating layer 821b by anodic oxidation.

That is, when the base material 821a is formed of a metal material such as stainless or the like, the coating layer 821b may be formed by coating the surface on which the powders are put, with an aluminum material and then, the coating layer 821b may be oxidized, thereby forming the pattern layer 821c having the texture pattern formed thereon.

Also, when the base material 821a is formed of a metal material such as stainless or the like, the pattern layer 821c may also be directly bonded to the base material 821a.

However, the present invention is not limited thereto, and the pattern layer 821c may also be formed by processing such as milling or the like.

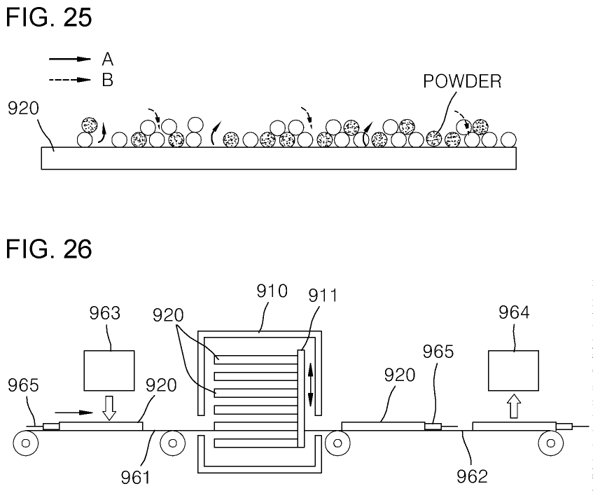

Meanwhile, FIG. 24 is a diagram schematically illustrating a plasma device for powder surface treatment using a horizontal electrode according to a ninth embodiment of the present invention. FIG. 25 is a diagram schematically illustrating the horizontal electrode shown in FIG. 24.

Referring to FIGS. 24 and 25, the plasma device for powder surface treatment using a horizontal electrode according to the ninth embodiment of the present invention includes a chamber 910, a horizontal electrode 920, and a vibration generator 930.

The powder includes nano- or micro-sized powder such as carbon nanotube, graphene or the like.

The horizontal electrode 920 is accommodated in the chamber 910, and the chamber 910 defines a space in which plasma is generated. A gas supply unit (not shown) that supplies external gas is connected to the chamber 910.

An example in which a rack 911 into which the horizontal electrode 920 is inserted, is provided inside the chamber 910, will be described.

The rack 911 may also be fixedly installed in the chamber 910 or may be installed to be picked out from the chamber 910 so that the rack 911 may also be brought into the chamber 910 after the horizontal electrode 920 is inserted into the rack 911.

The rack 911 is a second electrode unit for causing plasma discharge between the rack 911 and the horizontal electrode 920.

An example in which the rack 911 is grounded and serves as a ground electrode, will be described.

An example in which the rack 911 is provided with an insulating unit 912 and a connector 913, will be described.

The insulating unit 912 is provided in the rack 911 and is formed of an insulating body for electrical insulation between the horizontal electrode 920 and the rack 911. The shape or size of the insulating unit 912 may be variously changed and applicable.

The connector 913 is mounted in a groove formed in the rack 911, and the horizontal electrodes 920 are inserted into the connector 913 in a cartridge manner and is coupled thereto. The connector 913 is connected to the power supplying device 940 to be described later, via electrical wires or the like. However, the present invention is not limited thereto, and the horizontal electrode 920 may also be directly connected to the power supplying device 940 via electrical wires or the like.

The horizontal electrode 920 is a driving electrode that receives power from the power supplying device 940, and is a first electrode unit that causes plasma discharge between the horizontal electrode 920 and the rack 911 as the second electrode unit.

An example in which RF power is applied to the horizontal electrode 920 from the power supplying device 940, will be described. When RF power is applied to the horizontal electrode 920 and gas is supplied to the inside of the chamber 910 from the gas supply unit (not shown), plasma is generated inside the chamber 910.

Plasma generated in the horizontal electrode 920 is used to functionalize the powder by surface treatment. Through the surface functionalization of the powder, the powders are dispersed not to be aggregated without degradation of existing physical properties, and an interfacial bonding force between the powder and other heterogeneous materials can be enhanced.

The horizontal electrode 920 is arranged in the chamber 910 in the horizontal direction and has a flat plate shape so that the powder may be put on at least a part of an upper surface of the horizontal electrode 920s.

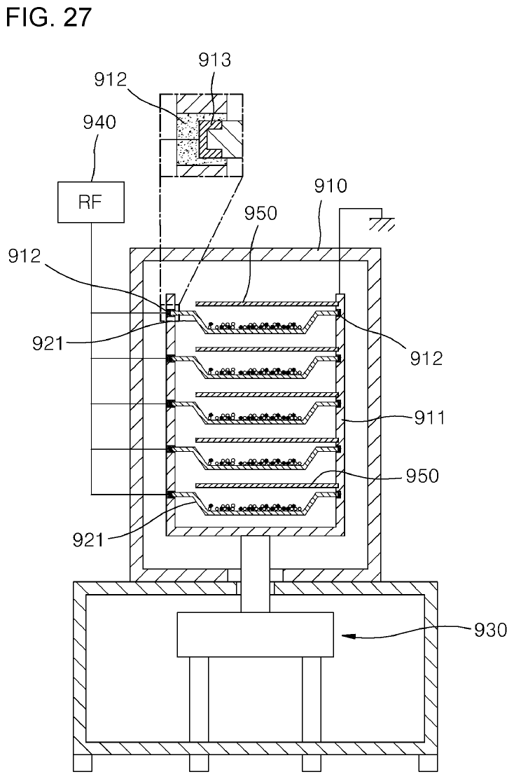

However, the present invention is not limited thereto, and the horizontal electrode 920 may be variously changed and applicable when the horizontal electrode 720 has any shape on which the powder may be put, such as circular plate or bowl shapes. For example, as shown in FIG. 27, only at least a part of a horizontal electrode may also be flatly formed.

In addition, the horizontal electrode 920 may be manufactured of various materials such as metal, polymer, ceramics and the like. The horizontal electrode 920 may also be manufactured of aluminum among metals and are lighter than other metals such as stainless and the like, and costs can be reduced.

Furthermore, the plurality of horizontal electrodes 920 are stacked in the vertical direction or the horizontal direction and are arranged to have separation spaces therebetween. In the present embodiment, an example in which the plurality of horizontal electrodes 920 are inserted into the rack 911 to be spaced apart from each other by a certain distance in the vertical direction, will be described. The number of stacks of the horizontal electrodes 920 may be adjusted according to the volume of treatment.

The vibration generator 930 is a device that applies vibration to the horizontal electrode 920 and allows the position of the powder to be changed on the upper surface of the horizontal electrode 920 so that the powder can be uniformly surface-treated. The vibration generator 930 may generate vibration such as the effect of tapping the lower part of the horizontal electrode 920, thereby changing the position of powder located relatively closer to the surface of the horizontal electrode 920 and the position of powder located relatively further from the surface of the horizontal electrode 920. Thus, the powders put on the upper surface of the horizontal electrodes 920 may be uniformly surface-treated. In the present embodiment, an example in which, when the vibration generator 930 is connected to the rack 911 and applies vibration to the rack 911, vibration is applied to the horizontal electrode 920 by vibration of the rack 911, will be described.

The vibration generator 930 may generate at least one of mechanical vibration, acoustic vibration, and ultrasonic vibration, thereby applying vibration to the horizontal electrode 920. Moreover, the vibration generator 930 may apply vibration so that the horizontal electrode 920 may perform various behaviors such as up and down motion, left and right motion, rotation, and gyro motion, and the like. Furthermore, the vibration generator 930 may apply vibration discontinuously or periodically.

An example in which the vibration generator 930 generates mechanical vibration when power is applied to the vibration generator 930 by the power supplying device, will be described. However, the present invention is not limited thereto, and the vibration generator may also be an ultrasonic vibrator or an acoustic vibration module.

The vibration generator 930 includes a vibration motor (not shown) that applies vibration to the horizontal electrode 920 by a rotational force when power is applied to the vibration generator 930, an air knocker (not shown) that applies vibration to the horizontal electrode 920 by moving a piston by a compressed air, and an electronic hammer (not shown) that applies vibration to the horizontal electrode 920 using an electromagnetic force generated when power is applied to the electronic hammer (not shown). However, the present invention is not limited thereto, and the vibration generator 930 may apply vibration to the horizontal electrode 920 so that the horizontal electrode 920 may perform various behaviors such as up and down motion, left and right motion, rotation, and gyro motion, etc. In addition, the vibration generator 930 may also apply vibration non-continuously or periodically.

The vibration motor (not shown) is a device that generates vibration by an eccentric rotation motion by connecting an eccentric axis to a rotational shaft of a motor, and is connected to the horizontal electrode 920 by a connection member.

The air knocker (not shown) is a device that moves the piston forwards by the compressed air supplied into a housing and transfers an impact due to the forward movement of the piston to the horizontal electrode 920, thereby generating vibration in the horizontal electrode 920. The air knocker (not shown) is arranged to face the horizontal electrode 920.

The electronic hammer (not shown) is a device that includes an E-type core and an I-type core inside to generate vibration in the horizontal electrode 920 using an electromagnetic force generated between the E-type core and the I-type core when power is applied to the electronic hammer (not shown).

In addition, the plasma device for powder surface treatment using a horizontal electrode includes a controller (not shown) that adjusts the intensity of vibration applied to the horizontal electrode 920 by controlling the operation of the vibration generator 930 according to the amount of the powder put on the horizontal electrode 920.

FIG. 26 is a diagram illustrating an example in which a plasma device for powder surface treatment using a horizontal electrode according to the ninth embodiment of the present invention is performed in a semi-continuous process.

Referring to FIG. 26, an example in which the plasma device for powder surface treatment using a horizontal electrode is performed in a semi-continuous process, will be described, and the plasma device for powder surface treatment using a horizontal electrode further includes a loading conveyor 961, an unloading conveyor 962, a rack ascending/descending unit (not shown), a powder supply unit 963, and a powder collecting unit 964.

The loading conveyor 961 is a moving device that moves the horizontal electrode 920 mounted on the movement jig 965 to the inside of the chamber 910.

The unloading conveyor 962 is a moving device that picks out the horizontal electrode 920 on which powder surface treatment has been completed, from the chamber 910 and moves the horizontal electrode 920.

The rack ascending/descending unit (not shown) is a device that ascends or descends the horizontal electrode 920 on which the powder surface treatment has been completed among the plurality of horizontal electrode 920 mounted on the rack 911 to the height of the unloading conveyor 962.

The powder supply unit 963 is a device that supplies the powders onto the upper surface of the horizontal electrode 920. The powder supply unit 963 is provided separately from the chamber 910, and supplies the powders onto the upper surface of the horizontal electrode 920 before the horizontal electrode 920 enters the chamber 910. That is, an example in which the powder supply unit 963 is provided on the upper side of the loading conveyor 961, will be described. However, the present invention is not limited thereto, and the powder supply unit 963 is provided inside the chamber 910, and the horizontal electrode 920 may also be supplied onto the upper surface of the horizontal electrode 920 in a state in which the horizontal electrode 920 is arranged in the chamber 910. Moreover, the powder supply unit 963 may be arranged in each separation space between the plurality of horizontal electrodes 920 and may also spray the powder into the separation spaces at one time, and one powder sprayer (not shown) may be installed to be movable in the vertical direction and may also spray the powders in each separation space between the horizontal electrodes 920. In addition, the powder sprayer (not shown) may also spray the powder into the chamber 910.

The powder collecting unit 964 is a device that collects the powders that are powder surface-treated on the upper surface of the horizontal electrodes 920. The powder collecting unit 964 is provided separately from the chamber 910 and collects the powder from the horizontal electrode 920 coming from the chamber 910. That is, an example in which the powder collecting unit 964 is provided on the upper side of the unloading conveyor 962, will be described. However, the present invention is not limited thereto, and the powder collecting unit 964 may also be provided in the chamber 910.

The operation of the plasma device for powder surface treatment using a horizontal electrodes according to the ninth embodiment of the present invention having the above configuration will be described.

Referring to FIG. 26, when the horizontal electrode 920 is put on the loading conveyor 961, the powder supply unit 963 supplies the powder onto the upper surface of the horizontal electrode 920.

The loading conveyor 961 moves the horizontal electrode 920 on which the powder is put, to the inside of the chamber 910.

The horizontal electrode 920 moved to the inside of the chamber 910 is inserted into the rack 911.

In this case, the rack ascending/descending unit (not shown) ascends or descends the horizontal electrode 920 so that an empty compartment of the rack 911 in which the horizontal electrode 920 is mounted, is located in a preset loading position. The loading position is pre-set to be identical to the height of the loading conveyor 961.

The horizontal electrode 920 is coupled to the connector 913 of the rack 911 in a cartridge manner.

When the horizontal electrode 920 is coupled to the connector 913 of the rack 911, the rack ascending/descending unit (not shown) returns the rack 911 to its original position where surface treatment is possible.

RF power is applied to the horizontal electrode 920 from the power supplying device 940 via the connector 913, and the rack 911 is grounded.

When power is applied to the horizontal electrode 920 and the rack 911 is grounded, plasma is concentrated between the horizontal electrode 920 and the rack 911 so that surface treatment of the powder can be more smoothly performed on the upper surface of the horizontal electrode 920.

Also, the vibration generator 930 is activated.

When the vibration generator 930 is activated, vibration is applied to the horizontal electrode 920 through the rack 911.

When vibration is applied to the horizontal electrode 920, the position of the powders is changed on the upper surface of the horizontal electrode 920 by vibration and the powders may be uniformly surface-treated. That is, since the vibration generator 930 generates the effect of tapping the horizontal electrode 920, the position of powder located relatively closer to the surface of the horizontal electrode 920 and the position of powder located relatively further from the surface of the horizontal electrode 920 are repeatedly changed.

That is, referring to FIG. 25, an adsorption force B in a direction toward the surface of the horizontal electrode 920 and a dispersion force A in a direction bouncing from the surface of the horizontal electrode 920 outwardly act on the powders put on the horizontal electrode 920. In this case, the adsorption force B and the dispersion force A may be adjusted according to the vibration intensity of the vibration generator 930. The adsorption force B and the dispersion force A may be calculated as optimum values by experiments or the like. The adsorption force B and the dispersion force A are properly adjusted so that only the position movement of the powder is possible while the powders do not fly from the surface of the horizontal electrode 920 and thus the powders can be uniformly plasma surface-treated.

Thus, the powders may be dispersed while the position movement of the powder is performed in the vertical direction and the horizontal direction using the vibration generator 930, the powder can be prevented from being stacked above a certain thickness in a specific portion of the surface of the horizontal electrode 920.

Moreover, since the effect of tapping the horizontal electrode 920 is given by the vibration generator 930, there is no need to completely remove the powders from the surface of the horizontal electrode 920, to float and disperse the powders and then to adsorb the powders and thus, a treatment time can be reduced compared to the case where the powder is floated, and the loss of the powder can be prevented.

In addition, since position movement is possible in a state in which the powders are adsorbed onto the surface of the horizontal electrode 920, the powders can be uniformly surface-treated by plasma.

The process in which the powder is surface-treated by plasma, may be performed for a preset time.

When there is the horizontal electrode 920 on which surface treatment has been completed, among the plurality of horizontal electrodes 920 mounted on the rack 911, the rack ascending/descending unit (not shown) moves the horizontal electrode 920 on which surface treatment has been completed, to a preset unloading position. The unloading position is pre-set to the height of the unloading conveyor 962.

The horizontal electrode 920 on which surface treatment has been completed, is picked out from the rack 911 by the movement jig 965.

The unloading conveyor 962 moves the horizontal electrode 920 picked out from the rack 911 to an outside of the chamber 910.

The powder collecting unit 964 collects the powders surface-treated on the surface of the horizontal electrode 920.

The horizontal electrode 920 from which the powders are collected, is moved to the loading conveyor 961 and is re-loaded.

As described above, since the plasma device for powder surface treatment using a horizontal electrode according to the present invention has a structure in which the plurality of horizontal electrodes 920 are stacked, the structure is very simple, and the volume that can be treated at one time can be maximized according to the number of stacks of the horizontal electrodes 920.

Moreover, since surface treatment is performed in a state in which the powders are put on the upper surface of the horizontal electrodes 920, the powders that are not treated but are discarded can be minimized compared to the case where the powders are floated and then are adsorbed. In addition, a process of repeatedly performing completely removing the powder from the surface of the horizontal electrodes 920 and floating and dispersing the powder is not required so that treatment efficiency can be enhanced.

Furthermore, vibration is applied to the horizontal electrode 920 using the vibration generator 930 so that the adsorption force B at which the powder is adsorbed onto the surface of the horizontal electrode 920 and the dispersion force A at which the powder is removed from the horizontal electrode 920, can be properly adjusted and thus the position movement of the powders is possible while the powder do not fly from the surface of the horizontal electrode 920 and the powders can be uniformly plasma surface-treated.

Meanwhile, FIG. 27 is a diagram schematically illustrating a plasma device for powder surface treatment using a horizontal electrode according to a tenth embodiment of the present invention.

Referring to FIG. 27, in the plasma device for powder surface treatment using a horizontal electrode according to the tenth embodiment of the present invention, the tenth embodiment is different from the ninth embodiment in that at least a part of a horizontal electrode 921 is formed in a concave dish shape and the second electrode unit includes the rack 911 and a cover electrode 950 that is coupled to the rack 911 and arranged to face the horizontal electrode 921, and the other configurations and operations of the tenth embodiment are similar to those of the ninth embodiment and thus, hereinafter, detailed descriptions of the similar configurations will be omitted, and different configurations will be mainly described in detail.

The cover electrode 950 is coupled to the rack 911 and is electrically connected to the rack 911. That is, the cover electrode 950 and the rack 911 have the same potential.

The cover electrode 950 is arranged to face the horizontal electrode 921 to be spaced apart from the upper surface of the horizontal electrode 921 upwardly by a certain distance.

An example in which the cover electrode 950 has a panel shape disposed to face a portion on which the powder is put, of the horizontal electrode 921 in the horizontal direction, will be described. However, the present invention is not limited thereto, and the size or shape of the cover electrode 950 may be variously changed and applicable.

An example in which only one end of the cover electrode 950 is coupled to the rack 911, will be described. However, the present invention is not limited thereto, and both ends of the cover electrode 950 may also be fixed only when a certain plasma discharge space may be formed between the horizontal electrode 921 and the cover electrode 950. A vertical separation distance between the cover electrode 950 and the horizontal electrode 921 may be pre-set to a distance at which plasma discharge efficiency is highest through experiments and the like.

In the present embodiment, an example in which the plurality of horizontal electrodes 921 are stacked in the vertical to be spaced apart from each other by a certain distance, will be described and thus, the cover electrode 950 is arranged between the plurality of horizontal electrodes 921.

In the present embodiment, an example in which RF power is applied to the horizontal electrode 921 and the rack 911 and the cover electrode 950 are grounded, will be described. That is, the rack 911 and the cover electrode 950 serve as ground electrodes.

As described above, when power is applied to the horizontal electrode 921 and the cover electrode 950 are grounded, plasma is more likely to be generated between the horizontal electrode 921 and the cover electrode 950 and thus, the effect of surface treatment of the powders can be maximized.

In the above embodiments, an example in which the first electrode unit receives RF power and the second electrode unit is grounded, has been described. However, the present invention is not limited thereto, and a certain alternating current (AC) power may also be applied between the first electrode unit and the second electrode unit.

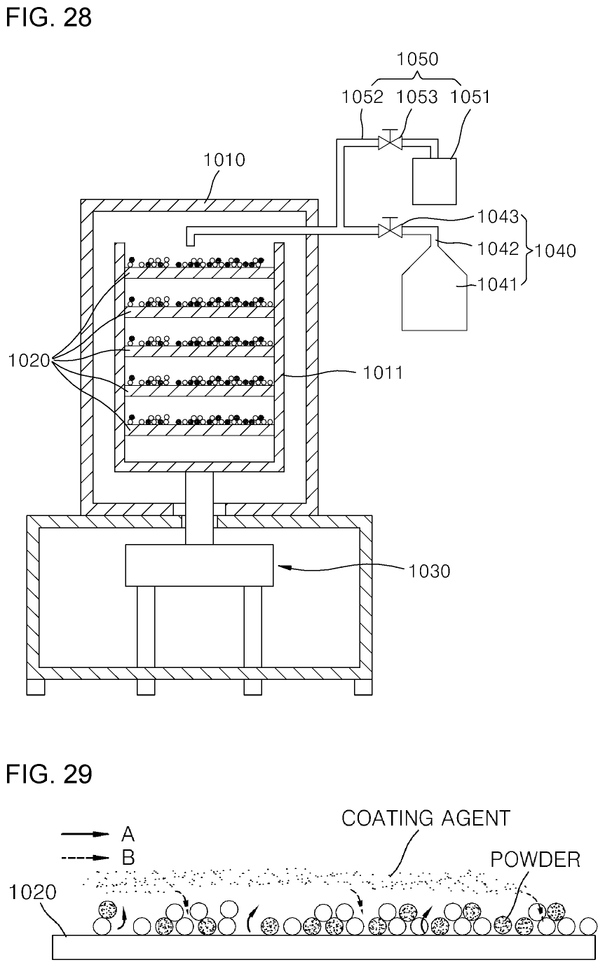

Meanwhile, FIG. 28 is a diagram schematically illustrating a plasma device for powder surface treatment using a horizontal electrode according to an eleventh embodiment of the present invention. FIG. 29 is a diagram schematically illustrating the horizontal electrode shown in FIG. 28.

Referring to FIGS. 28 and 29, the plasma device for powder surface treatment using a horizontal electrode according to the eleventh embodiment of the present invention includes a chamber 1010, a horizontal electrode 1020, a vibration generator 1030, a reaction gas supply unit 1040, and a coating source supply unit 1050.

The powder includes nano- or micro-sized powder such as carbon nanotube, graphene or the like.

The horizontal electrode 1020 is accommodated in the chamber 1010, and the chamber 1010 defines a space in which plasma is generated. A gas supply unit (not shown) that supplies external gas is connected to the chamber 1010.

An example in which a rack 1011 into which the horizontal electrode 1020 is inserted, is provided inside the chamber 1010, will be described.

The rack 1011 may also be fixedly installed in the chamber 1010 or may be installed to be picked out from the chamber 1010 so that the rack 1011 may also be brought into the chamber 1010 after the horizontal electrode 1020 is inserted into the rack 1011.

The horizontal electrode 1020 may be a power supply electrode to which power is supplied from the power supplying device (not shown). The horizontal electrode 1020 generates plasma inside the chamber 1010 when radio frequency (RF) power is applied from the power supplying device (not shown) and gas is supplied from the gas supply unit (not shown) into the chamber 1010.

In the present embodiment, an example in which the chamber 1010 or the rack 1011 is a ground electrode, will be described. However, the present invention is not limited thereto, and the horizontal electrode 1020 may also include electrodes having a potential difference between one side and the other side of the horizontal electrode 1020 to generate plasma.

Plasma generated in the horizontal electrode 1020 is used to functionalize the powder by surface treatment. Through surface functionalization of the powder, the powders are dispersed not to be aggregated without degradation of existing physical properties, and an interfacial bonding force between the powder and other heterogeneous materials can be enhanced.

The horizontal electrode 1020 is arranged in the chamber 1010 in the horizontal direction and has a flat plate shape so that the powder may be put on at least a part of the upper surface of the horizontal electrode 1020.

However, the present invention is not limited thereto, and the horizontal electrode 1020 may be variously changed and applicable when the horizontal electrode 1020 have any shape on which the powder may be put, such as circular plate or bowl shapes. For example, as shown in FIG. 31, only at least a part of a horizontal electrode 1020′ may also be flatly formed.

Moreover, the horizontal electrode 1020 may be manufactured of various materials such as metal, polymer, ceramics and the like. The horizontal electrode 1020 may also be manufactured of aluminum among metals and are lighter than other metals such as stainless and the like, and costs can be reduced.

Furthermore, the plurality of horizontal electrodes 1020 are stacked in the vertical direction or the horizontal direction and are arranged to have separation spaces therebetween. In the present embodiment, an example in which the plurality of horizontal electrodes 1020 are inserted into the rack 1011 to be spaced apart from each other by a certain distance in the vertical direction, will be described. The number of stacks of the horizontal electrodes 1020 may be adjusted according to the volume of treatment.

The vibration generator 1030 is a device that applies vibration to the horizontal electrode 1020 and allows the position of the powders to be changed on the upper surface of the horizontal electrode 1020 so that the powders can be uniformly surface-treated. The vibration generator 1030 may generate vibration such as the effect of tapping the lower part of the horizontal electrode 1020, thereby changing the position of powder located relatively closer to the surface of the horizontal electrode 1020 and the position of powder located relatively further from the surface of the horizontal electrode 1020. Thus, the powder put on the upper surface of the horizontal electrode 1020 may be uniformly surface-treated. In the present embodiment, an example in which, when the vibration generator 1030 is connected to the rack 1011 and applies vibration to the rack 1011, vibration is applied to the horizontal electrode 1020 by vibration of the rack 1011, will be described.

The vibration generator 1030 may generate at least one of mechanical vibration, acoustic vibration, and ultrasonic vibration, thereby applying vibration to the horizontal electrode 1020. In addition, the vibration generator 1030 may apply vibration so that the horizontal electrode 1020 may perform various behaviors such as up and down motion, left and right motion, rotation, and gyro motion, and the like. Furthermore, the vibration generator 1030 may apply vibration discontinuously or periodically.

An example in which the vibration generator 1030 generates mechanical vibration when power is applied to the vibration generator 1030 by the power supplying device, will be described. However, the present invention is not limited thereto, and the vibration generator may also be an ultrasonic vibrator or an acoustic vibration module.

The vibration generator 1030 includes a vibration motor (not shown) that applies vibration to the horizontal electrode 1020 by a rotational force when power is applied to the vibration generator 1030, an air knocker (not shown) that applies vibration to the horizontal electrode 1020 by moving a piston by a compressed air, and an electronic hammer (not shown) that applies vibration to the horizontal electrode 1020 using an electromagnetic force generated when power is applied to the electronic hammer (not shown). However, the present invention is not limited thereto, and the vibration generator 1030 may apply vibration to the horizontal electrode 1020 so that the horizontal electrode 1020 may perform various behaviors such as up and down motion, left and right motion, rotation, and gyro motion, etc. Furthermore, the vibration generator 1030 may also apply vibration non-continuously or periodically.

The vibration motor (not shown) is a device that generates vibration by an eccentric rotation motion by connecting an eccentric axis to a rotational shaft of a motor, and is connected to the horizontal electrode 1020 by a connection member.

The air knocker (not shown) is a device that moves the piston forwards by the compressed air supplied into a housing and transfers an impact due to the forward movement of the piston to the horizontal electrode 1020, thereby generating vibration in the horizontal electrode 1020. The air knocker (not shown) is arranged to face the horizontal electrode 1020.

The electronic hammer (not shown) is a device that includes an E-type core and an I-type core inside to generate vibration in the horizontal electrode 1020 using an electromagnetic force generated between the E-type core and the I-type core when power is applied to the electronic hammer (not shown).

Moreover, the plasma device for powder surface treatment using a horizontal electrode includes a controller (not shown) that adjusts the intensity of vibration applied to the horizontal electrode 1020 by controlling the operation of the vibration generator 1030 according to the amount of the powder put on the horizontal electrode 1020.

Meanwhile, the reaction gas supply unit 1040 includes a reaction gas tank 1041, a reaction gas supply flow path 1042 that connects the reaction gas tank 1041 and the chamber 1010 to each other, and a reaction gas valve 1043 that adjusts the flow rate of a reaction gas passing through the reaction gas supply flow path 1042.

An example in which the reaction gas supply unit 1040 supplies a plasma reaction gas to the inside of the chamber 1010, will be described. However, the present invention is not limited thereto, and the reaction gas supply flow path 1042 may also be formed to supply the plasma reaction gas to the upper surface of the horizontal electrode 1020. In the present embodiment, the plurality of horizontal electrode 1020 are provided and thus, the reaction gas supply flow path 1042 is branched into in plurality to face each upper surface of the plurality of horizontal electrode 1020 and the plasma reaction gas may also be supplied to each upper surface of the horizontal electrodes 102.

The coating source supply unit 1050 includes a coating source bubbler 1051, a coating source supply flow path 1052 that connects the coating source bubbler 1051 and the chamber 1010 to each other, and a coating source valve 1053 that adjusts the flow rate of the coating source passing through the coating source supply flow path 1052.

The coating source bubbler 1051 is a device that heats a liquid coating source through insulation heating to supply the heated coating source in a gaseous state according to the heated temperature.

An example in which the coating source supply flow path 1052 is connected to the reaction gas supply flow path 1042 and the coating source is supplied together with the plasma reaction gas, will be described. However, the present invention is not limited thereto, and the coating source supply flow path 1052 may also be provided separately from the reaction gas supply flow path 1042. Also, the coating source supply flow path 1052 may also supply the coating source to the inside of the chamber 101 and may also supply the coating source to each upper surface of the plurality of horizontal electrodes 1020.

The coating source (precursor) may be hexamethyldisiloxane (HDMSO) that is a liquid precursor so as to perform SiO₂ coating that is one of oxides, and for carbon-based coating, any one method such as vaporizing and injecting a liquid precursor or solid carbon including components that can be carbon-coated, may be used.

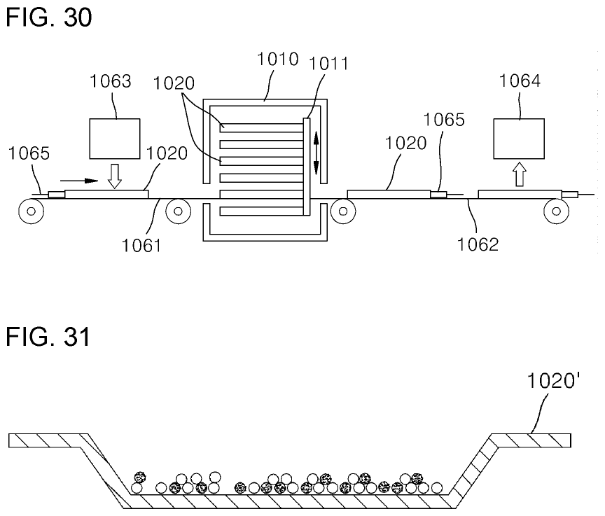

FIG. 30 is a diagram illustrating an example in which the plasma device for powder surface treatment using a horizontal electrode according to the eleventh embodiment of the present invention is performed in a semi-continuous process.

Referring to FIG. 30, an example in which the plasma device for powder surface treatment using a horizontal electrode is performed in a semi-continuous process, will be described, and the plasma device for powder surface treatment using a horizontal electrode further includes a loading conveyor 1061, an unloading conveyor 1062, a rack ascending/descending unit (not shown), a powder supply unit 1063, and a powder collecting unit 1064.

The loading conveyor 1061 is a movement device that moves the horizontal electrode 1020 mounted on a movement jig 1065 toward the inside of the chamber 1010.

The unloading conveyor 1062 is a movement device that picks out the horizontal electrode 1020 on which powder surface treatment has been completed, from the chamber 1010 and moves the horizontal electrode 1020.

The rack ascending/descending unit (not shown) is a device that ascends or descends the horizontal electrode 1020 on which the powder surface treatment has been completed among the plurality of horizontal electrodes 1020 mounted on the rack 1011 to the height of the unloading conveyor 1062.

The powder supply unit 1063 is a device that supplies the powders to the upper surface of the horizontal electrode 1020. The powder supply unit 1063 is separately provided from the chamber 1010 and supplies the powders to the upper surface of the horizontal electrode 1020 before the horizontal electrode 1020 enters the chamber 1010. That is, an example in which the powder supply unit 1063 is provided at an upper side of the loading conveyor 1061, will be described. However, the present invention is not limited thereto, and the powder supply unit 1063 may be provided inside the chamber 1010 and may also supply the powders to the upper surface of the horizontal electrode 1020 in a state in which the horizontal electrode 1020 is arranged in the chamber 1010. In addition, the powder supply unit 1063 may be arranged in each separation space between the plurality of horizontal electrodes 1020 to spray the powders into the separation spaces at one time, and one powder sprayer (not shown) may be installed to be movable in the vertical direction to spray the powders into each separation space between the horizontal electors 1020 continuously. Furthermore, the powder sprayer (not shown) may also spray the powder into the chamber 1010.

The powder collecting unit 1064 is a device that collects the powders that are powder surface-treated on the upper surface of the horizontal electrode 1020. The powder collecting unit 1064 is provided separately from the chamber 1010 and collects the powder from the horizontal electrode 1020 coming from the chamber 1010. That is, an example in which the powder collecting unit 1064 is provided on an upper side of the unloading conveyor 1062, will be described. However, the present invention is not limited thereto, and the powder collecting unit 1064 may also be provided in the chamber 1010.

The operation of the plasma device for powder surface treatment using a horizontal electrode according to the eleventh embodiment of the present invention having the above configuration will be described as below.

Referring to FIG. 30, when the horizontal electrode 1020 is put on the loading conveyor 1061, the powder supply unit 1063 supplies the powder onto the upper surface of the horizontal electrode 1020.

The loading conveyor 1061 moves the horizontal electrode 1020 on which the powder is put, to the inside of the chamber 1010.

The horizontal electrode 1020 moved to the inside of the chamber 1010 is inserted into the rack 1011.

In this case, the rack ascending/descending unit (not shown) ascends or descends the horizontal electrode 1020 so that an empty compartment of the rack 1011 in which the horizontal electrode 1020 is mounted, is located in a preset loading position. The loading position is pre-set to be identical to the height of the loading conveyor 1061.

The horizontal electrode 1020 is coupled to the connector 1013 of the rack 1011 in a cartridge manner.

When the horizontal electrode 1020 is coupled to the connector 1013 of the rack 1011, the rack ascending/descending unit (not shown) returns the rack 1011 to its original position where surface treatment is possible.

RF power is applied to the horizontal electrode 1020 from the power supplying device 1040 via the connector 1013, and the rack 1011 is grounded.

When power is applied to the horizontal electrode 1020 and the rack 1011 is grounded, plasma is concentrated between the horizontal electrode 1020 and the rack 1011 so that surface treatment of the powders can be more smoothly performed on the upper surface of the horizontal electrode 1020.

In addition, when the plasma reaction gas and the coating source are supplied, the coating source can be uniformly and more strongly coated onto the surface of the powders at the upper surface of the horizontal electrode 1020 by polymerization. That is, the coating source may be injected together in a plasma discharge state so that a gaseous coating source can be better coupled and coated onto the surface of the powder by polymerization.

Furthermore, the vibration generator 1030 is activated.

When the vibration generator 1030 is activated, vibration is applied to the horizontal electrode 1020 through the rack 1011.

When vibration is applied to the horizontal electrode 1020, the position of the powders is changed on the upper surface of the horizontal electrode 1020 by vibration and the powders may be uniformly surface-treated. That is, since the vibration generator 1030 generates the effect of tapping the horizontal electrode 1020, the position of powder located relatively closer to the surface of the horizontal electrode 1020 and the position of powder located relatively further from the surface of the horizontal electrode 1020 are repeatedly changed.

That is, referring to FIG. 29, an adsorption force B in a direction toward the surface of the horizontal electrode 1020 and a dispersion force A in a direction bouncing from the surface of the horizontal electrode 1020 outwardly act on the powders put on the horizontal electrode 1020. In this case, the adsorption force B and the dispersion force A may be adjusted according to the vibration intensity of the vibration generator 1030. The adsorption force B and the dispersion force A may be calculated as optimum values by experiments or the like. The adsorption force B and the dispersion force A are properly adjusted so that only the position movement of the powders is possible while the powders do not fly from the surface of the horizontal electrode 1020 and thus the powders can be uniformly plasma surface-treated.

Thus, the powder may be dispersed while the position movement of the powders is performed in the vertical direction and the horizontal direction using the vibration generator 1030, the powder can be prevented from being stacked above a certain thickness in a specific portion of the surface of the horizontal electrode 1020.

In addition, since the effect of tapping the horizontal electrode 1020 is given by the vibration generator 1030, there is no need to completely remove the powders from the surface of the horizontal electrode 1020, to float and disperse the powders and then to adsorb the powders and thus, a treatment time can be reduced compared to the case where the powder is floated, and the loss of the powder can be prevented.

Furthermore, since position movement is possible in a state in which the powders are adsorbed onto the surface of the horizontal electrode 1020, the powders can be uniformly surface-treated by plasma.

Moreover, the coating source can be more uniformly and strongly coated onto the surface of the horizontal electrode 1020.

The process in which the powder is surface-treated by plasma, may be performed for a preset time.

When there is the horizontal electrode 1020 on which surface treatment has been completed, among the plurality of horizontal electrodes 1020 mounted on the rack 1011, the rack ascending/descending unit (not shown) moves the horizontal electrode 1020 on which surface treatment has been completed, to a preset unloading position. The unloading position is pre-set to the height of the unloading conveyor 1062.

The horizontal electrode 1020 on which surface treatment has been completed, are picked out from the rack 1011 by the movement jig 1065.

The unloading conveyor 1062 moves the horizontal electrode 1020 removed from the rack 1011 to an outside of the chamber 1010.

The powder collecting unit 1064 collects the powders surface-treated on the surface of the horizontal electrodes 1020.

The horizontal electrode 1020 from which the powders are collected, is moved to the loading conveyor 1061 and is re-loaded.

As described above, since the plasma device for powder surface treatment using a horizontal electrode according to the present invention has a structure in which the plurality of horizontal electrodes 1020 are stacked, the structure is very simple, and the volume that can be treated at one time can be maximized according to the number of stacks of the horizontal electrodes 1020.

Furthermore, since surface treatment is performed in a state in which the powders are put on the upper surface of the horizontal electrode 1020, the powder that are not treated but are discarded can be minimized compared to the case where the powders are floated and then are adsorbed. Moreover, a process of repeatedly performing completely removing the powder from the surface of the horizontal electrodes 1020 and floating and dispersing the powder is not required so that treatment efficiency can be enhanced.

In addition, vibration is applied to the horizontal electrode 1020 using the vibration generator 1030 so that the adsorption force B at which the power is adsorbed onto the surface of the horizontal electrode 1020 and the dispersion force A at which the powder is removed from the horizontal electrode 1020, can be properly adjusted and thus the position movement of the powders is possible while the powders do not fly from the surface of the horizontal electrodes 1020 and the powders can be uniformly plasma surface-treated.

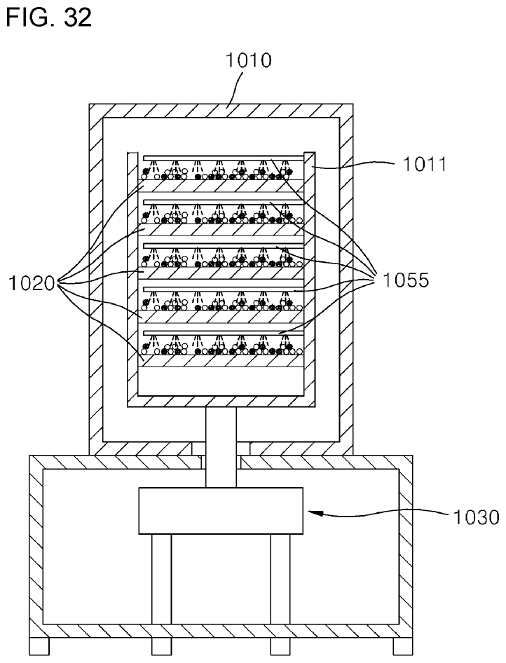

Meanwhile, FIG. 32 is a diagram schematically illustrating another example of a coating source supply unit in a plasma device for powder surface treatment using a horizontal electrode according to the eleventh embodiment of the present invention.

Referring to FIG. 32, a coating source supply unit may also include a coating source sprayer 1055 that sprays a gaseous coating source toward the horizontal electrodes 1020.

The coating source sprayer 1055 is provided on each upper surface of the horizontal electrode 1020 so that the coating source may be sprayed toward the powders put on each upper surface of the horizontal electrode 1020. Thus, the loss of the coating source can be minimized compared to the case where the coating source is supplied into the chamber 10101, and a portion excluding the horizontal electrodes 1020 can be prevented from being contaminated with the coating source.

An example in which the coating source sprayer 1055 is mounted on the rack 1011 and is formed long in the horizontal direction to face the horizontal electrode 1020, will be described. However, the present invention is not limited thereto, and the coating source sprayer 1055 may be mounted on the side surface of the rack 1011, may also spray the coating source laterally from the side surface of the rack 1011, may protrude from the horizontal electrode 1020 upwardly and may also spray the coating source in a lower direction toward the horizontal electrode 1020. That is, the coating source sprayer 1055 may be variously changed and applicable only when the coating source sprayer 1055 has any structure for spraying the coating source toward the upper surface of the horizontal electrode 1020.

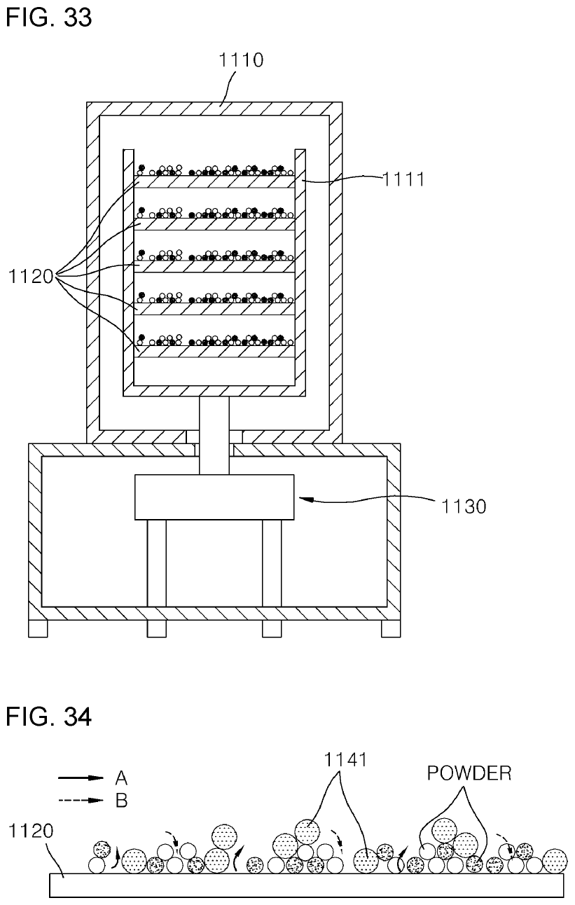

Meanwhile, FIG. 33 is a diagram schematically illustrating a plasma device for powder surface treatment using a horizontal electrode according to a twelfth embodiment of the present invention. FIG. 34 is a diagram schematically illustrating the horizontal electrode shown in FIG. 33.

Referring to FIGS. 33 and 34, the plasma device for powder surface treatment using a horizontal electrode according to the twelfth embodiment of the present invention includes a chamber 1110, a horizontal electrode 1120, a vibration generator 1130, and a powder grinding unit 1140.

The powder includes nano- or micro-sized powder such as carbon nanotube, graphene or the like.

The horizontal electrode 1120 is accommodated in the chamber 1110, and the chamber 1110 defines a space in which plasma is generated. A gas supply unit (not shown) that supplies external gas is connected to the chamber 1110.

An example in which a rack 1111 into which the horizontal electrode 1120 is inserted, is provided inside the chamber 1110, will be described.

The rack 1111 may also be fixedly installed in the chamber 1110 or may be installed to be picked out from the chamber 1110 so that the rack 1111 may also be brought into the chamber 1110 after the horizontal electrode 1120 is inserted into the rack 1111.

The horizontal electrode 1120 may be a power supply electrode to which power is supplied from the power supplying device (not shown). The horizontal electrode 1120 generates plasma inside the chamber 1110 when RF power is applied from the power supplying device (not shown) and gas is supplied from the gas supply unit (not shown) into the chamber 1110.

In the present embodiment, an example in which the chamber 1110 or the rack 1111 is a ground electrode, will be described. However, the present invention is not limited thereto, and the horizontal electrode 1120 may also include an electrode having a potential difference between one side and the other side of the horizontal electrode 1120 to generate plasma.

Plasma generated in the horizontal electrode 1120 is used to functionalize the powder by surface treatment. Through surface functionalization of the powder, the powders are dispersed not to be aggregated without degradation of existing physical properties, and an interfacial bonding force between the powder and other heterogeneous materials can be enhanced.

The horizontal electrode 1120 is arranged in the chamber 1110 in the horizontal direction and has a flat plate shape so that the powder may be put on at least a part of the upper surface of the horizontal electrodes 120.

However, the present invention is not limited thereto, and the horizontal electrode 1120 may be variously changed and applicable when the horizontal electrode 1120 has any shape on which the powder may be put, such as circular plate or bowl shapes. For example, as shown in FIG. 36, only at least a part of a horizontal electrode 1120′ may also be flatly formed.

Moreover, the horizontal electrode 1120 may be manufactured of various materials such as metal, polymer, ceramics and the like. The horizontal electrode 1120 may also be manufactured of aluminum among metals and may be lighter than other metals such as stainless and the like, and costs may be reduced.

Furthermore, the plurality of horizontal electrodes 1120 are stacked in the vertical direction or the horizontal direction and are arranged to have separation spaces therebetween. In the present embodiment, an example in which the plurality of horizontal electrodes 1120 are inserted into the rack 1111 to be spaced apart from each other by a certain distance in the vertical direction, will be described. The number of stacks of the horizontal electrodes 1120 may be adjusted according to the volume of treatment.

The vibration generator 1130 is a device that applies vibration to the horizontal electrode 1120 and allows the position of the powders to be changed on the upper surface of the horizontal electrode 1120 so that the powders may be uniformly surface-treated. The vibration generator 1130 may generate vibration such as the effect of tapping the lower part of the horizontal electrode 20, thereby changing the position of powder located relatively closer to the surface of the horizontal electrode 1120 and the position of powder located relatively further from the surface of the horizontal electrode 1120. Thus, the powders put on the upper surface of the horizontal electrode 1120 may be uniformly surface-treated. In the present embodiment, an example in which, when the vibration generator 1130 is connected to the rack 1111 and applies vibration to the rack 1111, vibration is applied to the horizontal electrode 1120 by vibration of the rack 1111, will be described.

The vibration generator 1130 may generate at least one of mechanical vibration, acoustic vibration, and ultrasonic vibration, thereby applying vibration to the horizontal electrode 1120. In addition, the vibration generator 1130 may apply vibration so that the horizontal electrode 1120 may perform various behaviors such as up and down motion, left and right motion, rotation, and gyro motion, and the like. Furthermore, the vibration generator 1130 may apply vibration discontinuously or periodically.

An example in which the vibration generator 1130 generates mechanical vibration when power is applied to the vibration generator 1130 by the power supplying device, will be described. However, the present invention is not limited thereto, and the vibration generator may also be an ultrasonic vibrator or an acoustic vibration module.

The vibration generator 1130 includes a vibration motor (not shown) that applies vibration to the horizontal electrode 1120 by a rotational force when power is applied to the vibration generator 1130, an air knocker (not shown) that applies vibration to the horizontal electrode 1120 by moving a piston by a compressed air, and an electronic hammer (not shown) that applies vibration to the horizontal electrode 1120 using an electromagnetic force generated when power is applied to the electronic hammer (not shown). However, the present invention is not limited thereto, and the vibration generator 1130 may apply vibration to the horizontal electrode 1120 so that the horizontal electrode 1120 may perform various behaviors such as up and down motion, left and right motion, rotation, and gyro motion, etc. Furthermore, the vibration generator 1130 may also apply vibration non-continuously or periodically.

The vibration motor (not shown) is a device that generates vibration by an eccentric rotation motion by connecting an eccentric axis to a rotational shaft of a motor, and is connected to the horizontal electrode 1120 by a connection member.

The air knocker (not shown) is a device that moves the piston forwards by the compressed air supplied into a housing and transfers an impact due to the forward movement of the piston to the horizontal electrode 1120, thereby generating vibration in the horizontal electrode 1120. The air knocker (not shown) is arranged to face the horizontal electrode 1120.

The electronic hammer (not shown) is a device that includes an E-type core and an I-type core inside to generate vibration in the horizontal electrode 1120 using an electromagnetic force generated between the E-type core and the I-type core when power is applied to the electronic hammer (not shown).

Moreover, the plasma device for powder surface treatment using a horizontal electrodes includes a controller (not shown) that adjusts the intensity of vibration applied to the horizontal electrode 1120 by controlling the operation of the vibration generator 1130 according to the amount of the powder put on the horizontal electrode 1120.

Meanwhile, the powder grinding unit 1140 mixes grinding mediums 1141 with the powders put on the horizontal electrode 1120, thereby grinding the powders when the powders and the grinding mediums 1141 collide with each other during surface treatment of the powders.

An example in which the powder grinding unit 1140 is a grinding medium supply unit that supplies the grinding mediums 1141 to the powder supply unit 1163 to be described later, will be described. However, the present invention is not limited thereto, and the powder grinding unit 1140 may also supply the grinding mediums 1141 directly to the upper surface of the horizontal electrode 1120.

In the present embodiment, an example in which the grinding mediums 1141 have a ball shape having a greater size than the size of the powders and formed of a metal material, will be described. However, the present invention is not limited thereto, and the grinding mediums 1141 may have the size that is equal to or greater than the size of the powders and may have various shapes such as beads and the like in addition to balls. Also, at least a part of the grinding mediums 1141 may be formed to have different sizes and shapes. That is, the grinding mediums 1141 may be variously changed and applicable when the horizontal electrode 1120 have any material, shape and size on which the powders can be ground while the grinding mediums 1141 collide with the powder.

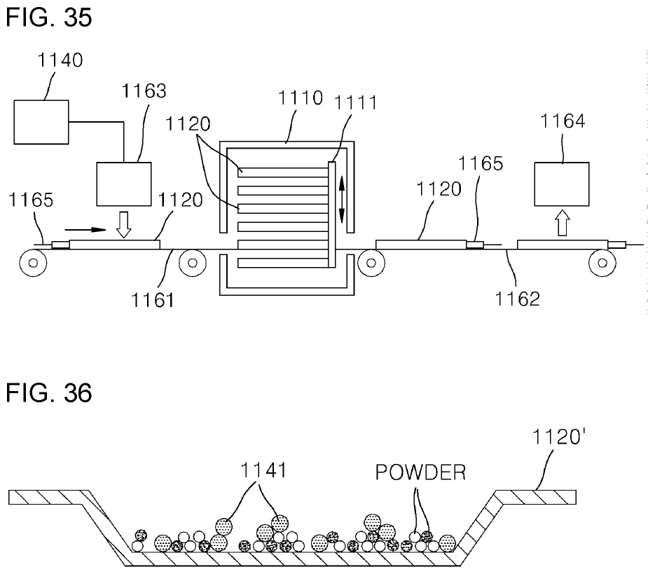

FIG. 35 is a diagram illustrating an example in which the plasma device for powder surface treatment using a horizontal electrode according to the twelfth embodiment of the present invention is performed in a semi-continuous process.

Referring to FIG. 35, an example in which the plasma device for powder surface treatment is performed in a semi-continuous process, will be described, and the plasma device for powder surface treatment using a horizontal electrode further includes a loading conveyor 1161, an unloading conveyor 1162, a rack ascending/descending unit (not shown), a powder supply unit 1163, and a powder collecting unit 1164.

The loading conveyor 1161 is a is a movement device that moves the horizontal electrode 1120 mounted on a movement jig 1165 toward the inside of the chamber 1110.

The unloading conveyor 1162 is a movement device that picks out the horizontal electrode 1120 on which powder surface treatment has been completed, from the chamber 1110 and moves the horizontal electrode 1120.

The rack ascending/descending unit (not shown) is a device that ascends or descends the horizontal electrode 1120 on which the powder surface treatment has been completed among the plurality of horizontal electrode 1120 mounted on the rack 811 to the height of the unloading conveyor 1162.

The powder supply unit 1163 is a device that supplies the powder to the upper surface of the horizontal electrode 1120. The powder supply unit 1163 is separately provided from the chamber 1110 and supplies the powders to the upper surface of the horizontal electrode 1120 before the horizontal electrode 1120 enters the chamber 1110. That is, an example in which the powder supply unit 1163 is provided at an upper side of the loading conveyor 1161, will be described. However, the present invention is not limited thereto, and the powder supply unit 1163 may be provided inside the chamber 1110 and may also supply the powders to the upper surface of the horizontal electrode 1120 in a state in which the horizontal electrode 1120 is arranged in the chamber 1110. In addition, the powder supply unit 1163 may be arranged in each separation space between the plurality of horizontal electrodes 1120 to spray the powders into the separation spaces at one time, and one powder sprayer (not shown) may be installed to be movable in the vertical direction to spray the powders into each separation space between the horizontal electors 1120 continuously. Moreover, the powder sprayer (not shown) may also spray the powder into the chamber 1110.

The powder collecting unit 1164 is a device that collects the powder that is powder surface-treated on the upper surface of the horizontal electrode 1120. The powder collecting unit 1164 is provided separately from the chamber 1110 and collects the powder from the horizontal electrode 1120 coming from the chamber 1110. That is, an example in which the powder collecting unit 1164 is provided on an upper side of the unloading conveyor 1162, will be described. However, the present invention is not limited thereto, and the powder collecting unit 1164 may also be provided in the chamber 1110.

The operation of the plasma device for powder surface treatment using a horizontal electrode according to the twelfth embodiment of the present invention having the above configuration will be described as below.

Referring to FIG. 35, when the horizontal electrode 1120 is put on the loading conveyor 1161, the powder supply unit 1163 supplies the powder onto the upper surface of the horizontal electrode 1120.

Here, an example in which the grinding mediums 1141 are supplied from the grinding medium supply unit 1140 to the powder supply unit 1163, will be described, and thus the powder and the grinding mediums 1141 are mixed with each other in the powder supply unit 1163.

Thus, the powder and the grinding mediums are put on the upper surface of the horizontal electrode 1120 through the powder supply unit 1163. However, the present invention is not limited thereto, and the grinding mediums may also be supplied to the upper surface of the horizontal electrode 1120 after the powders are supplied, and may also be separately supplied to the upper surface of the horizontal electrode 1120 inside the chamber 1110.

The loading conveyor 1161 moves the horizontal electrode 1120 on which the powder and the grinding mediums are put, to the inside of the chamber 1110.

The horizontal electrode 1120 moved to the inside of the chamber 1110 is inserted into the rack 1111.

In this case, the rack ascending/descending unit (not shown) ascends or descends the horizontal electrode 1120 so that an empty compartment of the rack 1111 in which the horizontal electrode 1120 is mounted, is located in a preset loading position. The loading position is pre-set to be identical to the height of the loading conveyor 1161.

The horizontal electrode 1120 is coupled to the connector 1113 of the rack 1111 in a cartridge manner.

When the horizontal electrode 1120 is coupled to the connector 1113 of the rack 1111, the rack ascending/descending unit (not shown) returns the rack 1111 to its original position where surface treatment is possible.

RF power is supplied to the horizontal electrode 1120 from the power supplying device 1140 through the connector 1113, and the rack 1111 is grounded.

When power is applied to the horizontal electrode 1120 and the rack 1111 is grounded, plasma is concentrated between the horizontal electrode 1120 and the rack 1111 so that surface treatment of the powders can be more smoothly performed on the upper surface of the horizontal electrode 1120.

In addition, when the vibration generator 1130 is activated, vibration is applied to the horizontal electrode 1120 through the rack 1111.

When vibration is applied to the horizontal electrode 1120, the position of the powders is changed on the upper surface of the horizontal electrode 1120 by vibration and the powders may be uniformly surface-treated. That is, since the vibration generator 1130 generates the effect of tapping the horizontal electrode 1120, the position of powder located relatively closer to the surface of the horizontal electrode 1120 and the position of powder located relatively further from the surface of the horizontal electrode 1120 are repeatedly changed.

That is, referring to FIG. 34, an adsorption force B in a direction toward the surface of the horizontal electrode 1120 and a dispersion force A in a direction bouncing from the surface of the horizontal electrode 1120 outwardly act on the powders put on the horizontal electrode 1120. In this case, the adsorption force B and the dispersion force A may be adjusted according to the vibration intensity of the vibration generator 1130. The adsorption force B and the dispersion force A may be calculated as optimum values by experiments or the like. The adsorption force B and the dispersion force A are properly adjusted so that only the position movement of the powders is possible while the powder do not fly from the surface of the horizontal electrode 1120 and thus the powders can be uniformly plasma surface-treated.

Thus, the powders may be dispersed while the position movement of the powders is performed in the vertical direction and the horizontal direction using the vibration generator 1130, the powder can be prevented from being stacked above a certain thickness in a specific portion of the surface of the horizontal electrode 1120.

Furthermore, since the effect of tapping the horizontal electrode 1120 is given by the vibration generator 1130, there is no need to completely remove the powders from the surface of the horizontal electrode 1120, to float and disperse the powders and then to adsorb the powders and thus, a treatment time can be reduced compared to the case where the powder is floated, and the loss of the powder can be prevented.

In addition, since position movement is possible in a state in which the powders are adsorbed onto the surface of the horizontal electrode 1120, the powders can be uniformly surface-treated by plasma.

Furthermore, during surface treatment of plasma, when vibration is applied to the horizontal electrode 1120, the powders and the grinding mediums 1141 collide with each other so that the powders can be ground with a smaller size and dispersed. Thus, the effect of mechanical grinding can be achieved by the grinding mediums 1141, and surface treatment efficiency can be increased.

The process in which the powder is surface-treated by plasma, may be performed for a preset time.

When there is the horizontal electrode 1120 on which surface treatment has been completed, among the plurality of horizontal electrodes 1120 mounted on the rack 1111, the rack ascending/descending unit (not shown) moves the horizontal electrode 1120 on which surface treatment has been completed, to a preset unloading position. The unloading position is pre-set to the height of the unloading conveyor 1162.

The horizontal electrode 1120 on which surface treatment has been completed, are picked out from the rack 1111 by the movement jig 1165.

The unloading conveyor 1162 moves the horizontal electrode 1120 picked out from the rack 1111 to an outside of the chamber 810.

The powder collecting unit 1164 collects the powder surface-treated on the surface of the horizontal electrode 1120.

The horizontal electrode 1120 from which the powders are collected, is moved to the loading conveyor 1161 and is re-loaded.

As described above, since the plasma device for powder surface treatment using a horizontal electrode according to the present invention has a structure in which the plurality of horizontal electrode 1120 are stacked, the structure is very simple, and the volume that can be treated at one time can be maximized according to the number of stacks of the horizontal electrode 1120.

Moreover, since surface treatment is performed in a state in which the powders are put on the upper surface of the horizontal electrode 1120, the powders that are not treated but are discarded can be minimized compared to the case where the powders are floated and then are adsorbed. In addition, a process of repeatedly performing completely removing the powder from the surface of the horizontal electrode 1120 and floating and dispersing the powder is not required so that treatment efficiency can be enhanced.

Furthermore, vibration is applied to the horizontal electrode 1120 using the vibration generator 1130 so that the adsorption force B at which the powers are adsorbed onto the surface of the horizontal electrode 1120 and the dispersion force A at which the powders are removed from the horizontal electrode 1120, can be properly adjusted and thus the position movement of the powders is possible while the powders do not fly from the surface of the horizontal electrode 1120 and the powders can be uniformly plasma surface-treated.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

According to the present invention, a plasma device for powder surface treatment using a horizontal electrode, in which surface treatment can be more quickly and uniformly performed, can be manufactured.

1-36. (canceled)

37. A plasma device for powder surface treatment using a horizontal electrode, the plasma device comprising:
a horizontal electrode installed inside a chamber that forms a space in which plasma is generated, in a horizontal direction, being flatly formed so that powders are put on at least a part of an upper surface of the horizontal electrode and configured to generate plasma when power is applied to the horizontal electrodes, to functionalize the powders by performing surface treatment on the powders; and
a vibration generator configured to apply vibration to the horizontal electrode to allow a position of the powders to be changed on the upper surface of the horizontal electrode, thereby uniformly surface-treating the powders.

38. The plasma device of claim 37, wherein the vibration generator is further configured to apply vibration to the horizontal electrode so that the horizontal electrode performs at least one of up and down motion, left and right motion, rotation and gyro motion.

39. The plasma device of claim 38, wherein the vibration generator comprises a vibration motor connected to the horizontal electrode and configured to apply vibration to the horizontal electrode by a rotational force when power is applied to the horizontal electrode.

40. The plasma device of claim 37, further comprising a heater configured to heat the horizontal electrode to remove residual moisture of the powders.

41. The plasma device of claim 37, further comprising a magnetic force generator configured to generate a magnetic force in the periphery of the horizontal electrode to increase plasma density.

42. The plasma device of claim 41, wherein the magnetic force generator comprises a magnet mounted on the horizontal electrode or inserted into the horizontal electrode.

43. The plasma device of claim 41, wherein the magnetic force generator comprises a plurality of magnets having a ring shape with different sizes, arranged to be spaced apart from each other by a certain distance in a radiation direction and having N-poles and S-poles alternately arranged therein.

44. The plasma device of claim 37, wherein at least a part of the upper surface of the horizontal electrode is textured with a preset texture pattern to have preset surface roughness.

45. The plasma device of claim 37, further comprising a second electrode unit installed inside the chamber and causing plasma discharge between the second electrode unit and a first electrode unit including the horizontal electrode.

46. The plasma device of claim 45, wherein the second electrode unit comprises a rack installed inside the chamber and detachably coupled to the horizontal electrode.

47. The plasma device of claim 46, wherein the second electrode unit further comprises a cover electrode coupled to the rack, electrically connected to the rack to have the same potential and arranged to face the horizontal electrode while being spaced apart from the upper surface of the horizontal electrode upwards by a certain distance.

48. The plasma device of claim 46, wherein the rack is provided with a connector to which the horizontal electrode is coupled and which is connected to a power supplying device, and an insulating unit for insulation between the connector and the rack.

49. The plasma device of claim 47, wherein a plurality of the horizontal electrode are detachably coupled to the rack and are stacked and arranged to be spaced apart from each other by a certain distance in a vertical direction, and a plurality of cover electrodes are arranged between the plurality of the horizontal electrode.

50. The plasma device of claim 37, further comprising:
a reaction gas supply unit configured to supply a plasma reaction gas to the inside of the chamber; and
a coating source supply unit configured to coat the surface of the powder by plasma polymerization when the plasma is generated, by supplying a gaseous coating source (precursor) to the inside of the chamber.

51. The plasma device of claim 50, wherein the reaction gas supply unit comprises:
a reaction gas supply flow path on which the plasma reaction gas is supplied to the upper surface of the horizontal electrode; and
a reaction gas valve provided on the reaction gas supply flow path and configured to adjust a flow rate of the plasma reaction gas.

52. The plasma device of claim 50, wherein the coating source supply unit comprises:
a coating source supply flow path on which the coating source is supplied to the upper surface of the horizontal electrode; and
a coating source valve provided on the coating source supply flow path and configured to adjust a flow rate of the coating source.

53. The plasma device of claim 52, wherein the coating source supply unit comprises:
a coating source supply flow path, which is connected to the reaction gas supply flow path and on which the coating source is supplied to the reaction gas supply flow path; and
a coating source valve provided on the coating source supply flow path and configured to adjust a flow rate of the coating source.

54. The plasma device of claim 50, wherein the coating source supply unit comprises a coating source sprayer configured to spray the coating source toward the upper surface of the horizontal electrodes.

55. The plasma device of claim 37, further comprising a powder grinding unit configured to mix grinding mediums with the powders and to allow the powders and the grinding mediums to collide with each other so that the powders are ground, when power is applied to the horizontal electrode and vibration is applied to the horizontal electrode.

56. The plasma device of claim 55, wherein at least a part of the grinding mediums has different sizes and shapes.
